(19) United States
(12) Patent Application Publication
(10) Pub. No.: US 2026/0047134 A1
(43) Pub. Date: Feb. 12, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Takanori MATSUZAKI, Atsugi (JP); Yoshiaki OIKAWA, Atsugi (JP)

(21) Appl. No.: 19/127,215

(22) PCT Filed: Nov. 24, 2023
(86) PCT No.: PCT/IB2023/061856

§ 371 Date: May 5, 2025

(30) Foreign Application Priority Data
Dec. 1, 2022 (JP) 2022-192587

(51) Int. Cl. H10D 30/67; H10K 59/121

(52) U.S. Cl. CPC H10D 30/673; H10D 30/6728; H10K 59/1213

(57) ABSTRACT

A semiconductor device including a transistor, a first insulating layer, and a second insulating layer is provided. The transistor includes first to third conductive layers, a semiconductor layer, and a third insulating layer. The first insulating layer positioned above the first conductive layer includes an opening reaching the first conductive layer. The semiconductor layer includes a portion in contact with the top surface of the first conductive layer in the opening, a portion along a side surface and over of the first insulating layer. The third insulating layer covers the semiconductor layer in the opening. The third conductive layer covers the third insulating layer in the opening. The second insulating layer covers the third conductive layer. The second conductive layer includes a portion positioned over the third conductive layer with the second insulating layer therebetween.

### TECHNICAL FIELD

One embodiment of the present invention relates to a transistor, a semiconductor device, a memory device, a display device, and an electronic appliance.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic appliance, a lighting device, an input device, an input/output device, a driving method thereof, and a manufacturing method thereof. A semiconductor device generally means a device that can function by utilizing semiconductor characteristics.

### BACKGROUND ART

In recent years, development of semiconductor devices has progressed, and CPUs, memories, and other LSIs are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of a CPU, a memory, or another LSI is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current. Furthermore, for example, Patent Document 2 discloses a memory device that can retain stored contents for a long time.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 each disclose a technique to achieve an integrated circuit with higher density by making a plurality of memory cells overlap with each other by stacking a first transistor using an oxide semiconductor film and a second transistor using an oxide semiconductor film. Furthermore, Patent Document 4 discloses a vertical transistor in which a side surface of an oxide semiconductor is covered with a gate electrode with a gate insulator therebetween.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be easily miniaturized. Another object is to provide a semiconductor device that can be highly integrated. Another object is to provide a semiconductor device with reduced parasitic capacitance. Another object is to provide a semiconductor device with a reduced wiring load. Another object is to provide a semiconductor device having high reliability. Another object is to provide a semiconductor device exhibiting favorable electrical characteristics. Another object is to provide a semiconductor device that operates at high speed.

An object of one embodiment of the present invention is to provide a semiconductor device, a memory device, a display device, or an electronic appliance having a novel structure. Another object of one embodiment of the present invention is to at least alleviate at least one of problems in the conventional art.

Note that the description of these objects does not preclude the presence of other objects. One embodiment of the present invention does not need to achieve all these objects. Objects other than these can be derived from the description of the specification, the drawings, the claims, and the like.

### Means for Solving the Problems

One embodiment of the present invention is a semiconductor device including a transistor, a first insulating layer, and a second insulating layer. The transistor includes a first conductive layer, a second conductive layer, a third conductive layer, a semiconductor layer, and a third insulating layer. The first insulating layer is positioned above the first conductive layer and includes an opening reaching the first conductive layer. The semiconductor layer includes a portion in contact with the top surface of the first conductive layer in the opening, a portion in the opening along the side surface of the first insulating layer, and a portion over the first insulating layer. The third insulating layer covers the semiconductor layer in the opening. The third conductive layer covers the third insulating layer in the opening. The second insulating layer covers the third conductive layer. The second conductive layer includes a portion positioned over the third conductive layer with the second insulating layer therebetween and a portion in contact with the portion of the semiconductor layer positioned over the first insulating layer.

In the above, the second conductive layer preferably includes a portion extending in a first direction. Furthermore, the third conductive layer preferably includes a portion extending in a second direction intersecting with the first direction. In that case, the second conductive layer and the third conductive layer preferably intersect with each other in a region overlapping with the opening.

In the above, a fourth insulating layer and a fifth insulating layer each positioned inside the opening are preferably included. The fourth insulating layer is preferably provided between the semiconductor layer and the first insulating layer and includes a material less likely to diffuse hydrogen than the first insulating layer. The fifth insulating layer is preferably provided between the semiconductor layer and the fourth insulating layer and has a function of capturing or fixing hydrogen.

Furthermore, a sixth insulating layer positioned inside the opening is preferably included. In that case, the sixth insulating layer is preferably provided between the semiconductor layer and the fifth insulating layer and preferably includes an oxide.

In the above, the diameter of the opening is preferably larger than the height of the opening. In particular, the diameter of the opening is preferably more than or equal to twice as large as the height of the opening.

In the above, at least one of the first conductive layer and the second conductive layer preferably includes ruthenium.

### Effect of the Invention

According to one embodiment of the present invention, a semiconductor device that can be easily miniaturized can be provided. A semiconductor device that can be highly integrated can be provided. A semiconductor device with reduced parasitic capacitance can be provided. A semiconductor device with a reduced wiring load can be provided. A semiconductor device having high reliability can be provided. A semiconductor device exhibiting favorable electrical characteristics can be provided. A semiconductor device that operates at high speed can be provided.

According to one embodiment of the present invention, a semiconductor device, a memory device, a display device, or an electronic appliance having a novel structure can be provided. According to one embodiment of the present invention, at least one of problems in the conventional art can be at least alleviated.

Note that the description of these effects does not preclude the presence of other effects. One embodiment of the present invention does not need to have all these effects. Note that effects other than these can be derived from the description of the specification, the drawings, the claims, and the like.

### BRIEF DESCRIPTION OF THE DRAWINGS

FIG. 1A and FIG. 1B illustrate a structure example of a semiconductor device.

FIG. 2A to FIG. 2C illustrate a structure example of a semiconductor device.

FIG. 3A and FIG. 3B illustrate a structure example of a semiconductor device.

FIG. 4A to FIG. 4D each illustrate a structure example of a semiconductor device.

FIG. 5A to FIG. 5D each illustrate a structure example of a semiconductor device.

FIG. 6A to FIG. 6D each illustrate a structure example of a semiconductor device.

FIG. 7A to FIG. 7D each illustrate a structure example of a semiconductor device.

FIG. 8A to FIG. 8D each illustrate a structure example of a semiconductor device.

FIG. 9A to FIG. 9D are diagrams illustrating an example of a method for manufacturing a semiconductor device.

FIG. 10A to FIG. 10C are diagrams illustrating an example of a method for manufacturing a semiconductor device.

FIG. 11A to FIG. 11C are diagrams illustrating an example of a method for manufacturing a semiconductor device.

FIG. 12A to FIG. 12C are diagrams illustrating an example of a method for manufacturing a semiconductor device.

FIG. 13A to FIG. 13C illustrate a structure example of a memory device.

FIG. 14A to FIG. 14C illustrate a structure example of a memory device.

FIG. 15A and FIG. 15B illustrate a structure example of a memory device.

FIG. 16A and FIG. 16B illustrate a structure example of a memory device.

FIG. 17A and FIG. 17B illustrate a structure example of a memory device.

FIG. 18 illustrates a structure example of a memory device.

FIG. 19 illustrates a structure example of a memory device.

FIG. 20A and FIG. 20B illustrate a structure example of a memory device.

FIG. 21A to FIG. 21D illustrate a structure example of a memory device.

FIG. 22 illustrates a structure example of a memory device.

FIG. 23A and FIG. 23B illustrate a structure example of a display device.

FIG. 24 illustrates a structure example of a display device.

FIG. 25 illustrates a structure example of a display device.

FIG. 26 illustrates a structure example of a display device.

FIG. 27A to FIG. 27C illustrate a structure example of a display device.

FIG. 28A and FIG. 28B each illustrate a structure example of a display device.

FIG. 29A to FIG. 29D each illustrate a structure example of an electronic appliance.

FIG. 30A to FIG. 30F each illustrate a structure example of an electronic appliance.

FIG. 31A to FIG. 31G each illustrate a structure example of an electronic appliance.

FIG. 32A and FIG. 32B each illustrate a structure example of an electronic component.

FIG. 33A to FIG. 33C illustrate a structure example of a large computer.

FIG. 34A illustrates a structure example of space equipment. FIG. 34B illustrates a structure example of a storage system.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of the embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

A transistor is a kind of semiconductor element and enables amplification of a current or a voltage, switching operation for controlling conduction or non-conduction, and the like. A transistor in this specification includes an IGFET (Insulated Gate Field Effect Transistor) and a thin film transistor (TFT).

The functions of a “source” and a “drain” are sometimes replaced with each other when a transistor of different polarity is used or when the direction of current is changed in circuit operation, for example. Thus, the terms “source” and “drain” can be used interchangeably in this specification.

In this specification and the like, the term “electrically connected” includes the case where components are connected through an “object having any electric function”. There is no particular limitation on the “object having any electric function” as long as electric signals can be transmitted and received between components that are connected through the object. Examples of the “object having any electric function” are a switching element such as a transistor, a resistor, a coil, a capacitor, and an element with a variety of functions as well as an electrode and a wiring.

Note that in this specification and the like, a top surface shape of a component means the outline of the component in a plan view. A plan view means that the component is seen from a normal direction of a surface where the component is formed or from a normal direction of a surface of a support (e.g., a substrate) where the component is formed.

Note that in this specification and the like, the expression “having substantially the same top surface shapes” means that the outlines of stacked layers at least partly overlap with each other. For example, the case of processing an upper layer and a lower layer with the use of the same mask pattern or mask patterns that are partly the same is included. Note that in some cases, the outlines do not completely overlap with each other and the upper layer is positioned inward from the lower layer or the upper layer is positioned outward from the lower layer; such a case is also represented by the expression “having substantially the same top surface shapes”.

Note that the expressions indicating directions such as “over” and “under” are basically used to correspond to the directions of drawings. However, in some cases, the term “over” or “under” in the specification does not indicate a direction corresponding to the direction in the drawings for the purpose of easy description or the like. For example, in the description of the stacked order (or the formation order) of a stacked body or the like, even in the case where a surface on which the stacked body is provided (e.g., a formation surface, a support surface, a bonding surface, or a planar surface) is positioned above the stacked body in the drawings, the direction and the opposite direction are expressed using “under” and “over”, respectively, in some cases.

Note that in this specification and the like, a channel length direction of a transistor refers to one of the directions parallel to a straight line that connects a source region and a drain region in the shortest distance. In other words, a channel length direction corresponds to one of the directions of current flowing through a semiconductor layer when a transistor is in an on state. In addition, a channel width direction refers to a direction orthogonal to the channel length direction. Note that each of the channel length direction and the channel width direction is not fixed to one direction in some cases depending on the structure or the shape of a transistor.

In this specification and the like, the term “film” and the term “layer” can be interchanged with each other. For example, in some cases, the term “insulating layer” can be interchanged with the term “insulating film”.

### Embodiment 1

In this embodiment, a structure example of a semiconductor device of one embodiment of the present invention and an example of a manufacturing method thereof will be described. As an example of the semiconductor device, a transistor and a memory device including the transistor will be described below.

In the transistor of one embodiment of the present invention, a source electrode and a drain electrode are positioned at different heights (e.g., heights in a direction perpendicular to a substrate plane or an insulating plane where the transistor is provided), so that current flows in a semiconductor layer in the height direction. In other words, the channel length direction includes a component of a height direction (vertical direction), so that one embodiment of the present invention can also be referred to as a vertical transistor, a vertical-channel transistor, or the like.

More specifically, a first insulating layer functioning as a first spacer is provided to cover a lower electrode that is one of a source electrode and a drain electrode of the transistor, and a semiconductor layer that is in contact with the top surface of the lower electrode and whose channel is formed along the side surface of the first insulating layer is provided in an opening provided in the first insulating layer. Another part of the semiconductor layer is provided along the top surface of the first insulating layer outside the opening. In the opening, a gate insulating layer is provided along the semiconductor layer, and gate electrode is provided to overlap with the semiconductor layer with the gate insulating layer therebetween. A second insulating layer functioning as a second spacer is provided to cover the gate electrode, and an upper layer that is the other of the source electrode and the drain electrode of the transistor is provided over the second insulating layer. The semiconductor layer is in contact with the upper electrode in a region not covered with the second insulating layer.

Each of the gate electrode and the upper electrode can be used as a wiring. In that case, the gate electrode and the upper electrode can intersect with each other with the second insulating layer therebetween in a region overlapping with the opening provided in the first insulating layer. Thus, the intersection portion of the two wirings can be provided to overlap with the transistor; therefore, the occupation area can be significantly reduced as compared with the case where the two wirings and the transistor are provided separately.

When an insulating film having a higher thickness than the gate insulating layer is used as the second insulating layer between the gate electrode and the upper electrode, the parasitic capacitance generated between the gate electrode and the upper electrode can be reduced. For the second insulating layer, a material having a lower permittivity than the gate insulating layer is further preferably used.

For the semiconductor layer, an oxide semiconductor is preferably used. For example, to form a source region and a drain region using silicon, which is a typical material of a semiconductor, the regions need to be doped with an impurity functioning as a donor or an acceptor. However, in the vertical transistor of one embodiment of the present invention, it may be difficult to perform impurity doping on the semiconductor layer with high accuracy because the levels of a source and a drain are different from each other and the channel formation region is oriented in the vertical direction with respect to the substrate surface, for example. In contrast, the oxide semiconductor can form a low-resistance region without such impurity doping and can be connected to the source electrode and the drain electrode favorably; thus, a transistor having a three-dimensional structure as in one embodiment of the present invention can be manufactured with high yield.

In the opening of the first insulating layer, the semiconductor layer can be provided in contact with the side surface of the first insulating layer. Here, in the case where an oxide semiconductor is used for the semiconductor layer, an oxide insulating film is preferably used for the first insulating layer in contact with the oxide semiconductor layer. Here, the hydrogen concentration in the first insulating layer is preferably as low as possible in order to reduce the hydrogen concentration in the semiconductor layer.

Alternatively, a barrier layer having a function of preventing diffusion of hydrogen may be provided between the first insulating layer and the semiconductor layer. Moreover, a layer having a function of capturing or fixing hydrogen is preferably provided between the barrier layer and the semiconductor layer. Accordingly, diffusion of hydrogen included in the first insulating layer into the semiconductor layer can be prevented and the hydrogen concentration in the semiconductor layer can be reduced; thus, a semiconductor device having high reliability can be obtained. Note that an insulating layer including an oxide insulating film may be provided between the semiconductor layer and a layer capturing or fixing hydrogen, and the insulating layer and the semiconductor layer may be in contact with each other.

Here, the channel length of the transistor can be precisely adjusted by the thickness of the first insulating layer serving as the first spacer; thus, a variation in the channel length can be extremely smaller than that of a planar transistor. Furthermore, by reducing the thickness of the first insulating layer, a transistor with an extremely short channel length can be manufactured. For example, it is possible to manufacture a transistor with a channel length of 2 μm or shorter, 1 μm or shorter, 500 nm or shorter, 300 nm or shorter, 200 nm or shorter, 100 nm or shorter, 50 nm or shorter, 30 nm or shorter, or 20 nm or shorter and 5 nm or longer, 7 nm or longer, or 10 nm or longer. Thus, it is possible to achieve a transistor with an extremely short channel length that could not be achieved with a light-exposure apparatus for mass production. In addition, a transistor with a channel length of less than 10 nm can also be achieved without using an extremely expensive light-exposure apparatus used in the latest LSI technology.

Since the channel length can be controlled by the thickness of the first insulating layer, the thickness of the first insulating layer is preferably as small as possible. For example, when the diameter of the opening in the first insulating layer is D and the thickness of the first insulating layer is H, H is preferably smaller than D, and H is further preferably smaller than or equal to half of D. Note that although H is preferably as small as possible, H is preferably larger than one or both of the semiconductor layer and the gate insulating layer, and is further preferably larger than the sum of the thicknesses of the semiconductor layer and the gate insulating layer.

The transistor of one embodiment of the present invention can have an extremely short channel length, a reduced occupation area, a large amount of current flowing therethrough, small parasitic capacitance, and high operation speed. The transistor of one embodiment of the present invention can be applied to a variety of semiconductor devices, e.g., a memory device, an arithmetic device, a display device, and an imaging device.

More specific examples will be described below with reference to drawings.

### [Structure Example]

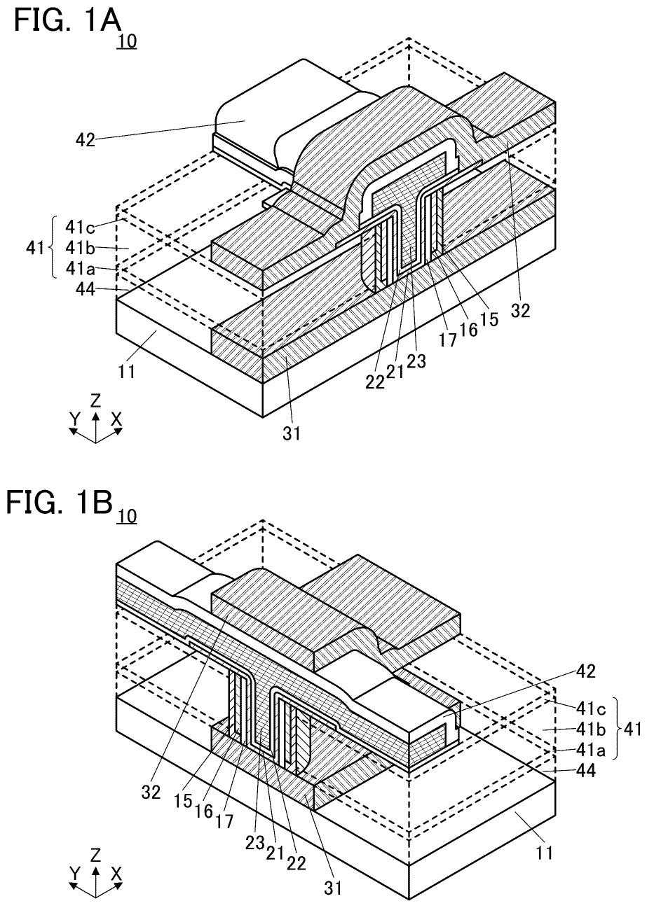

FIG. 1A and FIG. 1B each illustrate a perspective view of a transistor 10. The X direction, the Y direction, and the Z direction are indicated by arrows in each of the drawings. FIG. 1A is a perspective view including a cross-section of a plane perpendicular to the Y direction, and FIG. 1B is a perspective view including a cross-section of a plane perpendicular to the X direction.

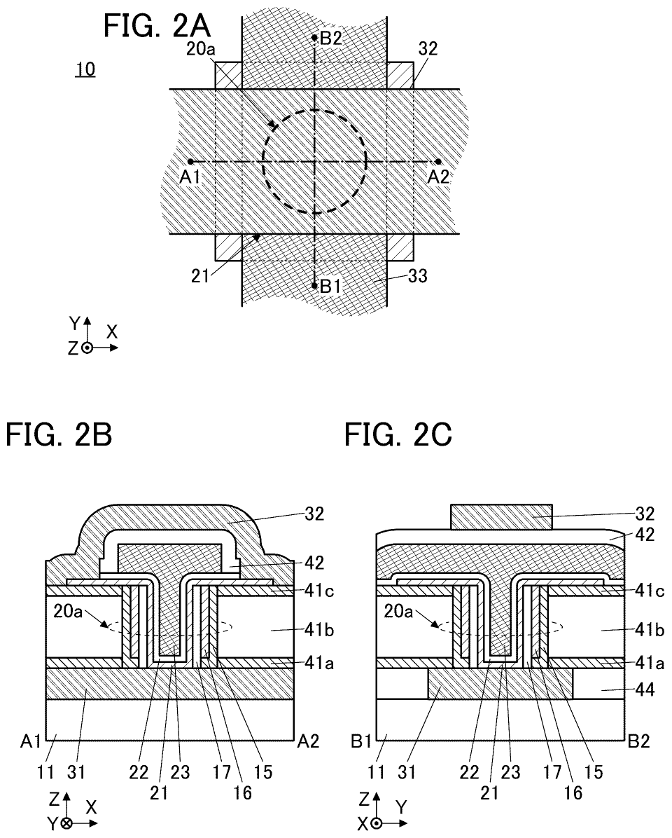

FIG. 2A is a plan view of the transistor 10, and FIG. 2B and FIG. 2C are schematic cross-sectional views along the cutting line A1-A2 and the line B1-B2, respectively, in FIG. 2A. Note that some components (e.g., insulating layers) are omitted in FIG. 2A.

The transistor 10 is provided over an insulating layer 11 provided over a substrate (not illustrated). The transistor 10 includes a conductive layer 31 serving as one of a source electrode and a drain electrode, a semiconductor layer 21, an insulating layer 22 serving as a gate insulating layer, a conductive layer 23 serving as a gate electrode, and a conductive layer 32 serving as the other of the source electrode and the drain electrode. Each of the conductive layer 23, the conductive layer 31, and the conductive layer 32 also serve as a wiring.

The conductive layer 31 is provided over the insulating layer 11, and an insulating layer 41a, an insulating layer 41b, and an insulating layer 41c (hereinafter collectively referred to as an insulating layer 41) are provided over the conductive layer 31. The insulating layer 41 includes an opening 20a reaching the conductive layer 31. The semiconductor layer 21 is provided along an inner wall (also referred to as a side surface or a side wall) of the opening 20a in the insulating layer 41 and is in contact with the top surface of the conductive layer 31. The insulating layer 22 includes a portion positioned inside the opening 20a and is provided to cover the semiconductor layer 21. The conductive layer 23 is provided to cover the insulating layer 22 inside the opening 20a. Here, an example is illustrated in which part of the conductive layer 23 fills the opening 20a and another part extends in the Y direction to function as a wiring. An insulating layer 42 is provided to cover the top surface and the side surface of the conductive layer 23, and the conductive layer 32 is provided over the insulating layer 42. The conductive layer 32 is in contact with the semiconductor layer 21 in a region not overlapping with the conductive layer 23, the insulating layer 22, or the insulating layer 42.

The conductive layer 31 is embedded in an insulating layer 44, the top surfaces of the conductive layer 31 and the insulating layer 44 are planarized, and the top surfaces of the conductive layer 31 and the insulating layer 44 are substantially level with each other. Such a structure is preferable because the adverse effect of a step can be eliminated or the adverse effect of a step can be reduced. The insulating layer 44 function as an interlayer insulating layer. For example, an inorganic insulating material having a low permittivity such as silicon oxide or silicon oxynitride is preferably used.

The conductive layer 23 and the conductive layer 32 overlap with each other with the insulating layer 42 positioned therebetween. Here, the conductive layer 23 extends in the Y direction, the conductive layer 32 extends in the X direction, and the conductive layer 23 intersects with the conductive layer 32 in a region overlapping with the opening 20a.

In the transistor 10 having such a structure, the source electrode and the drain electrode are positioned at different heights, so that current flows in the semiconductor in the height direction. In other words, the channel length direction can be regarded as having a component of the height direction (the vertical direction); accordingly, the transistor of one embodiment of the present invention can also be referred to as a VFET (Vertical Field Effect Transistor), a vertical transistor, a vertical-channel transistor, and the like. Since the source electrode, the semiconductor, and the drain electrode of the transistor 10 can be provided to overlap with each other, the area occupied by the transistor 10 can be significantly reduced as compared with that occupied by what is called a planar transistor (also referred to as a lateral transistor, an LFET (Lateral FET), or the like) in which a semiconductor is positioned over a flat plane. Note that the above-described vertical transistor may be referred to as a CFET (Columnar Field Effect Transistor) because of its shape.

The channel length of the transistor 10 can be precisely adjusted by the thickness of the insulating layer 41 serving as a spacer; thus, a variation in the channel length can be extremely smaller than that of a planar transistor. Furthermore, by reducing the thickness of the insulating layer 41, a transistor with an extremely short channel length can be manufactured. For example, it is possible to manufacture a transistor with a channel length of 50 nm or shorter, 30 nm or shorter, or 20 nm or shorter and 5 nm or longer, 7 nm or longer, or 10 nm or longer. Thus, even with a conventional light-exposure apparatus for mass production, a transistor with a channel length shorter than 10 nm can be achieved without using an extremely expensive light-exposure apparatus used in the latest LSI technology.

A variety of semiconductor materials can be used for the semiconductor layer 21; in particular, an oxide semiconductor including a metal oxide is preferably used. The use of an oxide semiconductor formed under an appropriate condition allows a transistor having both a high on-state current and an extremely low off-state current to be achieved at a low cost. Unless otherwise specified, preferable structure examples are described below given that an oxide semiconductor is used for the semiconductor layer 21.

The top surface of the conductive layer 31 is in contact with the semiconductor layer 21. Hence, in the case where an oxide semiconductor is used for the semiconductor layer 21, the exposed surfaces of the conductive layer 31 and vicinities thereof might be oxidized by, for example, the effect of heat applied in a deposition step of a semiconductor film to be the semiconductor layer 21 or a later step, so that an insulating oxide film is formed between the conductive layer and the semiconductor layer 21, increasing the contact resistance. Thus, an oxide conductor including a conductive oxide is preferably used at least for the uppermost part of the conductive layer 31. This can prevent an increase in the contact resistance due to oxidation of the surface of the conductive layer 31. The conductive layer 31 can also be referred to as an oxide layer, a metal oxide layer, an oxide conductor layer, or the like.

Note that the conductive layer 32 is in contact with the top surface of the semiconductor layer 21. Since there is no influence of heat applied in a formation step of the semiconductor layer 21, a conductive material such as a metal can be used for the conductive layer 32. Note that in the case where heat treatment is performed in the state where the conductive layer 32 and the semiconductor layer 21 are in contact with each other, the conductive layer 32 may react with a material included in the semiconductor layer 21 and be oxidized depending on the material of the conductive layer 32. Accordingly, an oxide conductor similar to that of the conductive layer 31 may be used.

The conductive layer 31 can be used as one of a source wiring and a drain wiring. The conductive layer 32 can be used as the other of the source wiring and the drain wiring. In the case where one or both of the conductive layer 31 and the conductive layer 32 are used as wiring(s) in this manner, they preferably have low electric resistance. Thus, a material having higher conductivity than an oxide conductor, such as a metal, an alloy, or a nitride thereof, is preferably used. In particular, one or both of the conductive layer 31 and the conductive layer 32 preferably have a stacked-layer structure including a layer of the material having high conductivity, where the above-described oxide conductor is preferably used at least for a portion in contact with the semiconductor layer 21.

Here, the transistor 10 is provided at an intersecting portion of the conductive layer 23 serving as the gate wiring and the conductive layer 32 serving as the source wiring or the drain wiring. Hence, parasitic capacitance is generated at the intersecting and overlapping portion of the conductive layer 23 and the conductive layer 32. Thus, the insulating layer 42 provided between the conductive layer 23 and the conductive layer 32 preferably has a larger thickness and a lower permittivity. The insulating layer 42 is preferably thicker than at least the insulating layer 22. Furthermore, the insulating layer 42 preferably has a material having a lower permittivity than at least the insulating layer 22. Thus, the capacitance between the conductive layer 23 and the conductive layer 32 can be effectively reduced. Although the insulating layer 42 is thicker than the conductive layer 32 in FIG. 1A, FIG. 1B, and the like, the present invention is not limited thereto. When the insulating layer 42 is thicker than one or both of the conductive layer 32 and the conductive layer 23, the conductive layer 32 and the conductive layer 23 can be relatively apart from each other, whereby the parasitic capacitance can be effectively reduced.

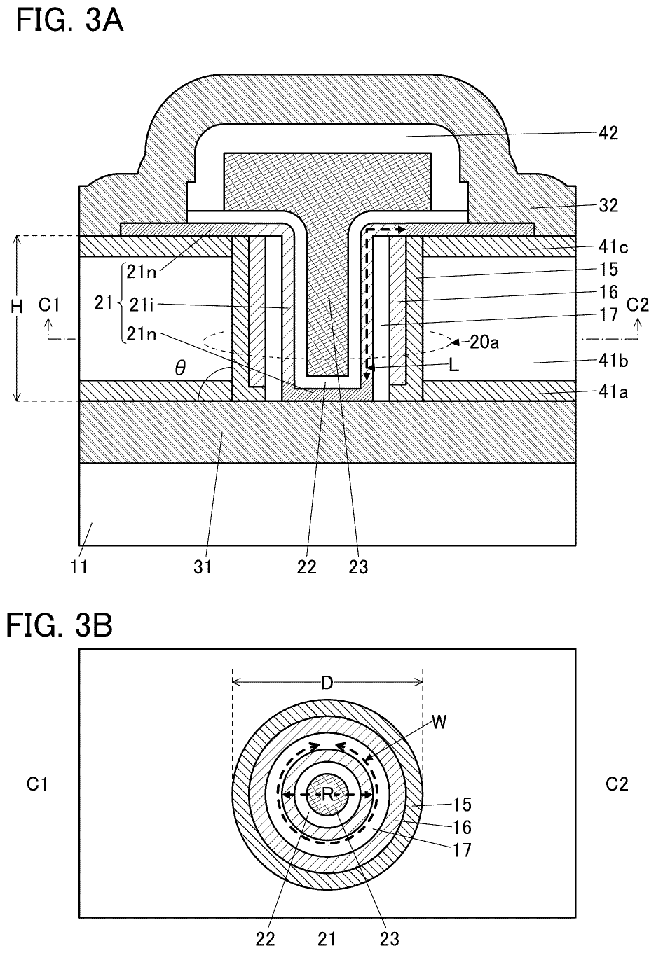

FIG. 2B and FIG. 2C illustrate the case where a stacked-layer film of the insulating layer 41a, the insulating layer 41b, and the insulating layer 41c is used for the insulating layer 41 in FIG. 1A and FIG. 1B. FIG. 3A illustrates an enlarged view of FIG. 2B.

An insulating layer 15 is provided between the insulating layer 41b and the semiconductor layer 21. An insulating layer 16 is provided between the semiconductor layer 21 and the insulating layer 15. An insulating layer 17 is provided between the semiconductor layer 21 and the insulating layer 16. Each of the insulating layer 15, the insulating layer 16, and the insulating layer 17 is positioned in an opening 20a and provided along the side surface of the insulating layer 41a.

The insulating layer 41b functions as an interlayer insulating layer. The insulating layer 41b is formed to be thicker than the other insulating layers (e.g., the insulating layer 41a and the insulating layer 41c) and thus is preferably formed by a deposition method with a high deposition speed. The insulating layer 41b is surrounded by the insulating layer 41a, the insulating layer 41c, and the insulating layer 15 and is not in contact with the semiconductor layer 21 and the conductive layers 31 and 32 that are in contact with the semiconductor layer 21. The insulating layer 41a, the insulating layer 41c, and the insulating layer 15 preferably have a barrier property against hydrogen. This can prevent hydrogen included in the insulating layer 41b from diffusing directly into the semiconductor layer 21 or indirectly into the semiconductor layer 21 through the conductive layer. Accordingly, a semiconductor device having favorable electrical characteristics and high reliability can be obtained.

The insulating layer 16 has a function of gettering (adsorbing, absorbing, capturing, or fixing) hydrogen. For example, when heat treatment is performed after the insulating layer 17 in contact with the insulating layer 16 is formed, hydrogen included in the insulating layer 17 can be captured and fixed by the insulating layer 16, so that the hydrogen concentration in the insulating layer 17 can be reduced.

Examples of the insulator having a function of gettering hydrogen include an oxide including magnesium and an oxide including one or both of aluminum and hafnium. These oxides preferably have an amorphous structure. In a metal oxide having an amorphous structure, an oxygen atom has a dangling bond and has a property of capturing or fixing hydrogen with the dangling bond in some cases. Note that such a metal oxide preferably has an amorphous structure, but may include a crystal region that is partly formed.

As the insulating layer 16, magnesium oxide, aluminum oxide, hafnium oxide, or the like can be used. Alternatively, for example, a stacked-layer film of aluminum oxide and silicon nitride over the aluminum oxide may be used for the insulating layer 16.

As the insulating layer 17 in contact with the semiconductor layer 21, an oxide insulating film is preferably used. For example, an inorganic insulating film such as a silicon oxide film or a silicon oxynitride film can be used. As the insulating layer 17, an oxide insulating film including oxygen excessively enough to release oxygen by heating is preferably used. When the insulating layer 17 that includes excess oxygen and has a reduced hydrogen concentration is provided in contact with the semiconductor layer 21, oxygen vacancies in the semiconductor layer 21 can be reduced, the hydrogen concentration can be reduced, and the transistor 10 having high reliability can be achieved.

A part of the semiconductor layer 21 that is in contact with the insulating layer 17 is a region where oxygen vacancies are reduced, i.e., an i-type region. Meanwhile, part of the semiconductor layer 21 that is not in contact with the insulating layer 17 is preferably an n-type region including a large amount of carriers. That is, the part of the semiconductor layer 21 that is in contact with the insulating layer 17 can be referred to as a channel formation region and an outer region thereof can be referred to as low-resistance region (also referred to as a source region or a drain region). In FIG. 3A, different hatching patterns are given to a channel formation region 21i and low-resistance regions 21n of the semiconductor layer 21. Here, an example in which a portion of the semiconductor layer 21 that is in contact with the insulating layer 41c, the insulating layer 15, or the conductive layer 31 is the low-resistance region 21n is illustrated.

A channel length L of the transistor 10 can be defined as, as illustrated in FIG. 3A, the length of a part of the semiconductor layer 21 that is in contact with the insulating layer 17 on the shortest path connecting a part in contact with the conductive layer 31 and a part in contact with the conductive layer 32. In an example illustrated in FIG. 3A, the channel formation region has an L-shaped cross-sectional shape.

Meanwhile, a channel width W of the transistor 10 depends on the shape of the opening 20a, the thicknesses of the insulating layers positioned in the opening 20a, and the like. FIG. 3B is a plan view obtained when a cross-section along the cutting line C1-C2 where the insulating layer 41b is provided in FIG. 3A is seen from the Z direction. Here, the opening 20a has a cylindrical shape. The insulating layer 15, the insulating layer 16, the insulating layer 17, the semiconductor layer 21, the insulating layer 22, and the conductive layer 23 are provided concentrically in this order from the outside in the opening 20a.

When the inner circle of the cross-section of the insulating layer 17 is a circle with a diameter R, the channel width W can be regarded as the circumference of the circle (i.e., =π×R). Here, the circumference of the opening 20a varies with the height if the sidewall angle θ of the opening 20a in the insulating layer 41 shifts from 90°. In that case, the circumference of the opening 20a with the minimum diameter may be regarded as the channel width W or the circumference of the opening 20a at the upper end may be regarded as the channel width W.

Since each of the insulating layer 15, the insulating layer 16, the insulating layer 17, the semiconductor layer 21, and the insulating layer 22 are formed in this order along the inner wall of the opening 20a in the insulating layer 41, their thicknesses are sometimes reduced in this portion by some deposition methods. For example, with a deposition method such as a sputtering method or a plasma CVD method used, a film deposited on a surface inclined or perpendicular to the substrate surface tends to be thinner than a film deposited on a surface horizontal to the substrate surface. By contrast, a deposition method such as an atomic layer deposition (ALD) method or a thermal CVD method allows a film with a uniform thickness to be formed on a surface with any angle. For example, the insulating layer 15, the insulating layer 16, the insulating layer 17, the semiconductor layer 21 and the insulating layer 22 are preferably formed by an ALD method when the angle θ is 75° or more, 80° or more, or 85° or more.

Here, the insulating layer 15 has an L-shaped cross-sectional shape so that part of the insulating layer 15 is positioned between the bottom surface of the insulating layer 16 and the top surface of the conductive layer 31. For example, such a shape can be obtained when an insulating film to be the insulating layer 15 and an insulating film to be the insulating layer 16 are successively formed and then part of these films is removed by etching.

As illustrated in FIG. 3A, the thickness of the insulating layer 41 (the insulating layer 41a, the insulating layer 41b, and the insulating layer 41c) is H, and as illustrated in FIG. 3B, the diameter of the opening 20a positioned in the insulating layer 41a is D. In this case, D is preferably larger than H, and D is further preferably more than or equal to twice as large as H. As described above, the channel length L of the transistor 10 depends on the thickness of the insulating layer 41; thus, the thinner the insulating layer 41 is, the shorter the channel length can be, and a large amount of current can flow therethrough. Furthermore, the channel width W can be increased with respect to the channel length L, so that a transistor capable of supplying a larger amount of current can be obtained.

### [Components]

### <Substrate>

As a substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples of the conductor substrate include a substrate including a nitride of a metal and a substrate including an oxide of a metal. Other examples include an insulator substrate provided with a conductive layer or a semiconductor layer, a semiconductor substrate provided with a conductive layer or an insulating layer, and a conductor substrate provided with a semiconductor layer or an insulating layer. Alternatively, these substrates provided with elements may be used. Examples of the element provided for the substrate include a capacitor, a resistor, a switching element, a light-emitting element, and a memory element.

### <Semiconductor Layer>

The semiconductor layer 21 preferably includes a metal oxide (an oxide semiconductor).

Examples of the metal oxide that can be used for the semiconductor layer 21 include In oxide, Ga oxide, and Zn oxide. The metal oxide preferably includes at least In or Zn. The metal oxide preferably includes two or three selected from In, an element M, and Zn. Note that the element M is a metal element or a metalloid element that has a high binding energy with oxygen, such as a metal element or a metalloid element whose binding energy with oxygen is higher than that of In, for example. Specific examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The element M included in the metal oxide is preferably one or more kinds of the above elements, and specifically, the element Mis preferably one or more kinds selected from Al, Ga, Y, and Sn, and is further preferably Ga. Note that a metal oxide including In, M, and Zn is hereinafter referred to as an In-M-Zn oxide in some cases. Note that in this specification and the like, a metal element and a metalloid element may be collectively referred to as a “metal element”, and a “metal element” in this specification and the like may refer to a metalloid element.

When a metal oxide is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood thereof. Note that a composition in the neighborhood includes the range of ±30% of an intended atomic ratio. By increasing the atomic ratio of indium in the metal oxide, the on-state current, field-effect mobility, or the like of the transistor can be increased.

The atomic ratio of In may be less than the atomic ratio of M in the In-M-Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood thereof. By increasing the atomic ratio of Min the metal oxide, generation of oxygen vacancies can be inhibited.

For the semiconductor layer 21, for example, In oxide, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, or In—Ga—Al—Zn oxide can be used. Alternatively, Ga—Zn oxide may be used.

Note that the metal oxide may include, instead of indium or in addition to indium, one or more kinds of metal elements with larger period numbers. As the overlap between orbits of metal elements is larger, the carrier conductivity in the metal oxide tends to be higher. Thus, when the transistor includes metal elements with larger period numbers, the field-effect mobility of the transistor can be increased in some cases. Examples of the metal elements with larger period numbers include metal elements belonging to Period 5 and metal elements belonging to Period 6. Specific examples of the metal elements include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may include one or more kinds of nonmetallic elements. When the metal oxide includes the nonmetallic elements, the field-effect mobility of the transistor can be increased in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used to form the metal oxide. In particular, the metal oxide is preferably formed by ALD, which enables good coverage. Note that in the case where the metal oxide is formed by a sputtering method, the composition of the formed metal oxide film may be different from the composition of a target. In particular, the content percentage of zinc in the deposited metal oxide film may be reduced to approximately 50% of that of the target.

In this specification and the like, the content of a certain metal element in the metal oxide refers to the ratio of the number of atoms of the element to the total number of atoms of metal elements included in the metal oxide. In the case where a metal oxide includes a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio of the metal element X to the metal element Y and the metal element Z included in the metal oxide is represented by B_{X}:B_{Y}:B_{Z}, the content of the metal element X can be represented by B_{X}/(B_{X}+B_{Y}+B_{Z}).

For example, in the case of the metal oxide including In, a higher content of In enables the transistor to have a high on-state current.

With use of a metal oxide that does not include Ga or has a low Ga content in the semiconductor layer 21, the transistor can be highly reliable against positive bias application. That is, the amount of change in the threshold voltage of the transistor in the PBTS (Positive Bias Temperature Stress) test can be small. Meanwhile, in the case of using a metal oxide that includes Ga, the Ga content is preferably lower than the In content. This achieves the transistor with high mobility and high reliability.

Meanwhile, the high content of Ga enables the transistor to be highly reliable against light. That is, the amount of change in the threshold voltage of the transistor in the NBTIS (Negative Bias Temperature Illumination Stress) test can be small. Specifically, in a metal oxide in which the atomic ratio of Ga is higher than or equal to that of In, the band gap is increased and accordingly the amount of change in the threshold voltage of the transistor in the NBTIS test can be reduced.

Furthermore, a metal oxide having a high zinc content has high crystallinity, whereby diffusion of impurities in the metal oxide can be inhibited. Consequently, a change in the electrical characteristics of the transistor can be inhibited and the reliability can be increased.

The semiconductor layer 21 may have a stacked-layer structure of two or more metal oxide layers. The two or more metal oxide layers included in the semiconductor layer 21 may have the same composition or substantially the same compositions. With the stacked-layer structure of metal oxide layers having the same composition, for example, the manufacturing cost can be reduced because the metal oxide layers can be formed with the same sputtering target. Note that a stacked-layer structure including two or more oxide semiconductor layers having different compositions may be employed. The use of an ALD method can form a metal oxide layer with a composition that continuously changes in the thickness direction. This not only increases the range of choices for design compared with the case of using a film with a predetermined composition but also prevents generation of an interface state or the like between two layers with different compositions; thus, the electrical characteristics and reliability can be improved.

In the case where the semiconductor layer 21 has a two-layer structure, the second layer, i.e., the layer closer to the gate electrode, preferably includes a material with higher mobility (higher conductivity) than the first layer. This enables the transistor to have normally-off characteristics and a high on-state current. Consequently, both low power consumption and high performance can be achieved. Alternatively, the first layer, i.e., the layer in contact with the source electrode and the drain electrode, may include a material having higher mobility than the material for the second layer. In that case, contact resistance between the semiconductor layer 21 and the source electrode or the drain electrode can be reduced and the parasitic resistance can be reduced accordingly, so that a transistor having a high on-state current can be obtained.

In the case where the semiconductor layer 21 has a three-layer structure, the second layer preferably uses a material having higher mobility than the first layer and the third layer. Accordingly, a transistor having a high on-state current and high reliability can be obtained.

The above-described differences in mobility and conductivity can be replaced with a difference in indium content, for example. The mobility and the conductivity are also affected by whether or not an element that contributes to an improvement in conductivity is included in addition to indium, by the content, or the like. Examples of the high-mobility material include a material having an atomic ratio of In:Ga:Zn=4:3:2 or in the neighborhood thereof, a material having an atomic ratio of In:Zn=1:1 or in the neighborhood thereof, a material having an atomic ratio of In:Zn=4:1 or in the neighborhood thereof, and a material having an atomic ratio of In:Sn:Zn=40:X:10 (X is greater than or equal to 0.1 and less than or equal to 5, typically X=1) or in the neighborhood thereof. Examples of a material having lower mobility or conductivity than the above-described materials include a material having an atomic ratio of In:Ga:Zn=1:3:2 or in the neighborhood thereof, a material having an atomic ratio of In:Ga:Zn=1:3:4 or in the neighborhood thereof, a material having an atomic ratio of In:Ga:Zn=2:2:1 or in the neighborhood thereof, a material having an atomic ratio of In:Ga:Zn=1:1:1 or in the neighborhood thereof, and a material having an atomic ratio of In:Ga:Zn=1:1:2 or in the neighborhood thereof.

It is preferable to use a metal oxide layer having crystallinity as the semiconductor layer 21. For example, a metal oxide layer having a CAAC (c-axis aligned crystal) structure, a polycrystalline structure, a microcrystalline (nc: nano-crystal) structure, or the like can be used. With the use of the metal oxide layer having crystallinity as the semiconductor layer 21, the density of defect states in the semiconductor layer 21 can be reduced, which enables the semiconductor device to have high reliability.

The higher the crystallinity of the metal oxide layer used as the semiconductor layer 21 is, the lower the density of defect states in the semiconductor layer 21 can be. By contrast, the use of a metal oxide layer with low crystallinity enables a transistor through which a large amount of current can flow.

A transistor using an oxide semiconductor (hereinafter also referred to as an OS transistor) has much higher field-effect mobility than a transistor using amorphous silicon. In addition, an OS transistor has an extremely low leakage current flowing between a source and a drain in an off state (hereinafter also referred to as off-state current), and charge accumulated in a capacitor that is connected in series to the transistor can be retained for a long period. Furthermore, the power consumption of the semiconductor device can be reduced with the OS transistor.

The semiconductor device that is one embodiment of the present invention can be used for a display device, for example. To increase the emission luminance of a light-emitting device included in a pixel circuit of a display device, it is necessary to increase the amount of current flowing through the light-emitting device. For that purpose, the source-drain voltage of a driving transistor included in the pixel circuit needs to be increased. Since an OS transistor has higher withstand voltage between the source and the drain than a transistor including silicon (hereinafter referred to as a Si transistor), a high voltage can be applied between the source and the drain of the OS transistor. Thus, by using an OS transistor as the driving transistor included in the pixel circuit, the amount of current flowing through the light-emitting device can be increased, resulting in an increase in the emission luminance of the light-emitting device.

When transistors operate in a saturation region, a change in source-drain current with respect to a change in gate-source voltage can be smaller in an OS transistor than in a Si transistor. Accordingly, when an OS transistor is used as the driving transistor included in the pixel circuit, the amount of current flowing through the light-emitting device can be precisely controlled. Accordingly, the number of gray levels in the pixel circuit can be increased. Moreover, current can be made flow stably even when the electrical characteristics (e.g., resistance) of the light-emitting device change or a variation in the electrical characteristics of the light-emitting device occurs.

As described above, by using an OS transistor as the driving transistor included in the pixel circuit, it is possible to achieve “inhibition of black floating”, “increase in emission luminance”, “increase in the number of gray levels”, “inhibition of the effect due to a manufacturing variation in light-emitting devices”, and the like.

A change in the electrical characteristics of an OS transistor due to irradiation with radiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that the semiconductor material that can be used for the semiconductor layer 21 is not limited to the oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may include an impurity as a dopant.

Alternatively, the semiconductor layer 21 may include a layered substance that functions as a semiconductor. The layered substance is a general term of a group of materials having a layered crystal structure. In the layered crystal structure, layers formed by covalent bonding or ionic bonding are stacked with bonding such as the Van der Waals bonding, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substances include graphene, silicene, and chalcogenide. Chalcogenide is a compound including chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 21, and any of an amorphous semiconductor, a single crystal semiconductor, and a semiconductor having crystallinity other than single crystal (a polycrystalline semiconductor, a microcrystalline semiconductor, or a semiconductor partly including crystal regions) may be used. A semiconductor having crystallinity is preferably used because degradation of the transistor characteristics can be inhibited.

### <Gate Insulating Layer>

The insulating layer 22 serves as the gate insulating layer of the transistor as well as a dielectric layer of a capacitor. In the case where an oxide semiconductor is used for the semiconductor layer 21, an oxide insulating film is preferably used as at least a film of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, aluminum nitride oxide, or the like can also be used. The insulating layer 22 may also have a stacked-layer structure, e.g., a stacked-layer structure including at least one oxide insulating film and at least one nitride insulating film.

Note that in this specification and the like, an oxynitride refers to a material that includes more oxygen than nitrogen. A nitride oxide refers to a material that includes more nitrogen than oxygen.

The insulating layer 22 is preferably formed with a stack of insulating materials formed of high-k materials, and preferably has a stacked-layer structure of a high relative dielectric constant (high-k) material and a material having higher dielectric strength than the high-k material. As the insulating layer 22, an insulating film in which zirconium oxide, aluminum oxide, and zirconium oxide are stacked in this order (also referred to as ZAZ) can be used, for example. Alternatively, an insulating film in which zirconium oxide, aluminum oxide, zirconium oxide, and aluminum oxide are stacked in this order (also referred to as ZAZA) can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of a capacitor.

A material that exhibits ferroelectricity may also be used for the insulating layer 22. Examples of the material that exhibits ferroelectricity include metal oxides such as hafnium oxide, zirconium oxide, and HfZrO_{X} (X is a real number greater than 0).

### <Conductive Layer>

The top surfaces of the conductive layer 31 and the conductive layer 32 is in contact with the semiconductor layer 21. Here, when an oxide semiconductor is used for the semiconductor layer 21 and a metal that is likely to be oxidized such as aluminum is used for a portion of the conductive layer 31 or the conductive layer 32 that is in contact with the semiconductor layer 21, for example, an insulating oxide (e.g., aluminum oxide) is formed between the conductive layer 31 or the conductive layer 32 and the semiconductor layer 21, which might prevent electrical continuity therebetween. Therefore, a conductive material that is less likely to be oxidized, a conductive material that maintains low electric resistance even after being oxidized, or an oxide conductive material is preferably used for at least the portions of the conductive layer 31 and the conductive layer 32 that are in contact with the semiconductor 21.

For example, it is preferable to use titanium, tantalum nitride, titanium nitride, a nitride including titanium and aluminum, a nitride including tantalum and aluminum, ruthenium, ruthenium oxide, ruthenium nitride, an oxide including strontium and ruthenium, an oxide including lanthanum and nickel, or the like for the conductive layer 31 and the conductive layer 32. These materials are preferable because they are conductive materials that are less likely to be oxidized or materials that maintain the conductivity even after being oxidized.

Alternatively, a conductive oxide such as indium oxide, zinc oxide, In—Sn oxide, In—Zn oxide, In—W oxide, In—W—Zn oxide, In—Ti oxide, In—Ti—Sn oxide, In—Sn—Si oxide, or Ga—Zn oxide can be used. A conductive oxide including indium is particularly preferable because of its high conductivity. Alternatively, the above-described oxide material such as In—Ga—Zn oxide that can be used for the semiconductor layer 21 can be used for the conductive layer when the carrier concentration is increased.

For the conductive layer 31 and the conductive layer 32, any of the following structures can be used: a single-layer structure of the above conductive oxide film, a three-layer structure in which a titanium nitride film, a tungsten film, and a titanium nitride are stacked in this order, a two-layer structure in which a ruthenium film or a ruthenium oxide film is stacked over a tungsten film, a two-layer structure in which a ruthenium film or a ruthenium oxide film is stacked over the above conductive oxide film, a two-layer structure in which the above conductive oxide film is stacked over a ruthenium film or a ruthenium oxide film, or the like, for example. Note that ruthenium is a material that is not easily etched and thus is preferably as thin as possible when used; ruthenium used preferably has a thickness greater than or equal to 0.1 nm and less than or equal to 2 nm, for example.

The conductive layer 23 serves as a gate electrode and a variety of conductive materials can be used. For the conductive layer 23, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; or an alloy including any of the above metal elements as its component, for example. It is also possible to use a nitride of any of the above metals or the alloy or an oxide of any of the above metals or the alloy. For example, it is preferable to use tantalum nitride, titanium nitride, tungsten, a nitride including titanium and aluminum, a nitride including tantalum and aluminum, ruthenium oxide, ruthenium nitride, an oxide including strontium and ruthenium, an oxide including lanthanum and nickel, or the like. Alternatively, a semiconductor having high electrical conductivity, typified by polycrystalline silicon including an impurity element such as phosphorus, or silicide such as nickel silicide may be used.

For the conductive layer 23, the nitride and the oxide that can be used for the conductive layer 31 and the conductive layer 32 may be used.

The conductive layer 23, the conductive layer 31, and the conductive layer 32 function also as wirings; thus, stacked low-resistance conductive materials is preferably used.

### <Insulating Layer>

The insulating layer 17 includes a portion in contact with the semiconductor layer 21. In the case where an oxide semiconductor is used for the semiconductor layer 21, an oxide is preferably used for at least the portion of the insulating layer 17 that is in contact with the semiconductor layer 21 in order to improve the properties of the interface between the semiconductor layer 21 and the insulating layer 17. For example, silicon oxide or silicon oxynitride can be suitably used. The insulating layer 17 can be formed with the use of a deposition method such as a sputtering method, an ALD method, or a plasma CVD method. In particular, the insulating layer 17 is preferably formed by an ALD method.

Further preferably, a film from which oxygen is released by heating is used for the insulating layer 17. Accordingly, oxygen is supplied to the semiconductor layer 21 owing to heat applied during the manufacturing process of the transistor 10; thus, oxygen vacancies in the semiconductor layer 21 can be reduced, and reliability can be improved. Examples of a method for supplying oxygen to the insulating layer 17 include heat treatment in an oxygen atmosphere and plasma treatment in an oxygen atmosphere.

The insulating layer 41b, the insulating layer 42, and the insulating layer 44 can be used as interlayer insulating films. For example, by using a sputtering method, which is a deposition method that does not use a hydrogen gas for a deposition gas, a film having an extremely low hydrogen content can be formed. Consequently, supply of hydrogen to the semiconductor layer 21 is inhibited and the electrical characteristics of the transistor 10 can be stabilized.

Since the insulating layer 41b, the insulating layer 42, and the insulating layer 44 serve as interlayer insulating layers, these are preferably formed by a deposition method that enables a higher deposition rate than those of the other insulating layers. For example, a film of TEOS (Tetra-Ethyl-Ortho-Silicate, Chemical Formula: Si(OC₂H₅)₄), formed by a plasma CVD method can also be used for the insulating layer 41b, the insulating layer 42, and the insulating layer 44. Thus, the productivity can be improved.

For the insulating layer 41a, the insulating layer 41c, and the insulating layer 15, films in which hydrogen is less likely to diffuse are preferably used. When the insulating layer 41b is sandwiched between the underlying insulating layer 41a and the overlying insulating layer 41c in which hydrogen is less likely to diffuse and the insulating layer 15 is provided on the side surface of the insulating layer 41b, oxygen can be enclosed in the insulating layer 41b. Accordingly, hydrogen that might diffuse into the semiconductor layer 21 can be effectively reduced.

For the insulating layer 41a, the insulating layer 41c, and the insulating layer 15, for example, one or more of silicon nitride, silicon nitride oxide, silicon oxynitride, aluminum oxide, aluminum oxynitride, aluminum nitride, hafnium oxide, and hafnium aluminate can be used. In particular, silicon nitride and silicon nitride oxide, which release fewer impurities (e.g., water and hydrogen) and are less likely to transmit oxygen and hydrogen, can be suitably used for the insulating layer 41a, the insulating layer 41c, and the insulating layer 15.

### VARIATION EXAMPLES

Examples of a structure that is partly different from the above-described structure example are described below. Note that description of the same portion as above is omitted in some cases.

### Variation Example 1

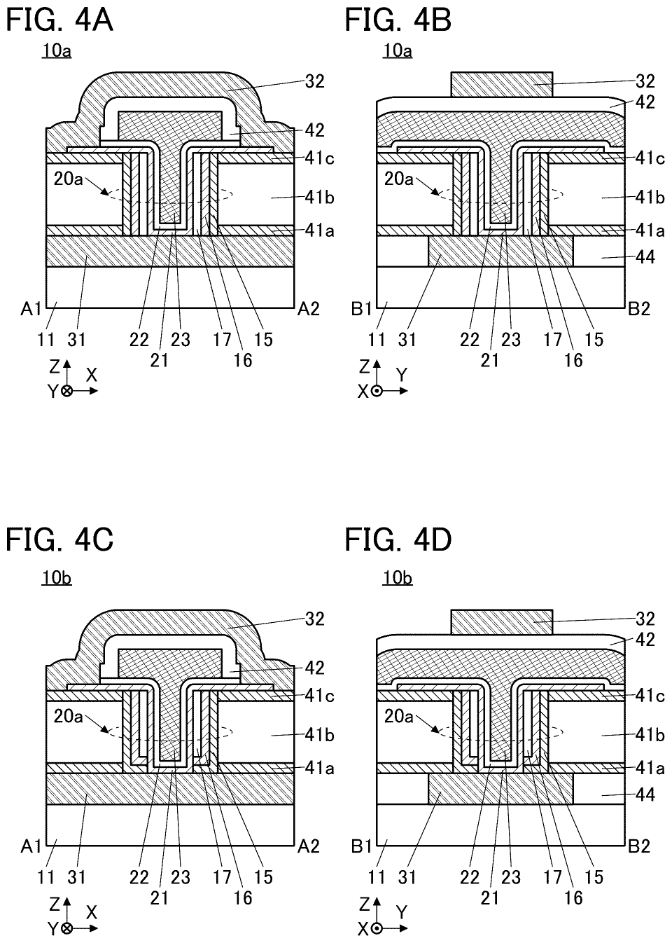

FIG. 4A and FIG. 4B are schematic cross-sectional views of a transistor 10a. Like FIG. 2B, FIG. 4A is a cross-sectional view along a cut surface parallel to an extending direction of the conductive layer 32, and like FIG. 2C, FIG. 4B is a cross-sectional view of a cross-section of the conductive layer 23 parallel to the extending direction. The transistor 10a is different from that of the transistor 10 mainly in the shape of the insulating layer 15.

In the transistor 10a, the cross-sectional shape of the insulating layer 16 is not an L shape but a linear shape. Accordingly, the bottom surface of the insulating layer 16 is in contact with the conductive layer 31. With such a structure, the contact area between the insulating layer 17 and the insulating layer 16 is increased, so that the hydrogen concentration in the insulating layer 17 can be reduced more effectively.

### Variation Example 2

A transistor 10b illustrated in FIG. 4C and FIG. 4D is an example in which each of the cross-sectional shapes of the insulating layer 15 and the insulating layer 16 have an L shape, the bottom surface of the insulating layer 16 is provided over the protruding portion of the insulating layer 15, and the bottom surface of the insulating layer 17 is provided over the protruding portion of the insulating layer 16. With such a structure, when the insulating layer 15, the insulating layer 16, and the insulating layer 17 are formed, three insulating films can be successively deposited and then collectively etched.

Part of the insulating layer 15 is in contact with a lower portion of the semiconductor layer 21. When a portion of the semiconductor layer 21 that is in contact with the conductive layer 31 is not in contact with the insulating layer 17, the carrier concentration of the portion is increased, so that an n-type region is easily formed. Thus, current in an on state of the transistor 10b can be increased.

### Variation Example 3

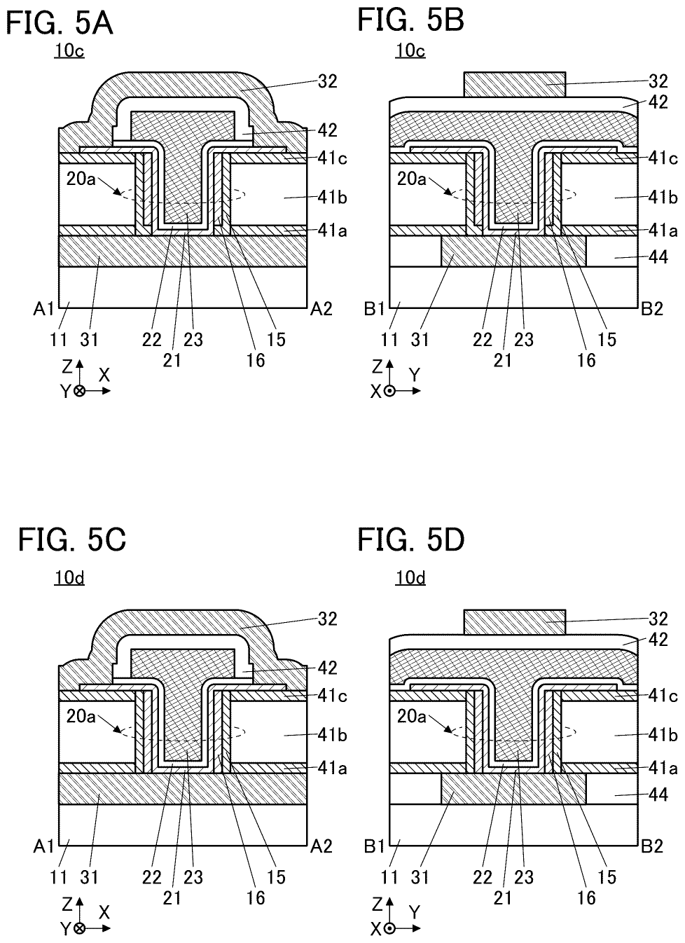

A transistor 10c illustrated in FIG. 5A and FIG. 5B is different from the transistor 10 mainly in not including the insulating layer 17.

Since the insulating layer 17 is not included, the insulating layer 16 is provided in contact with the semiconductor layer 21. Thus, hydrogen in the semiconductor layer 21 can be directly gettered by the insulating layer 16, so that the hydrogen concentration in the semiconductor layer 21 can be effectively reduced. Accordingly, a transistor having higher reliability can be achieved. When the insulating layer 17 is not provided, the manufacturing process can be shortened and the productivity can be improved.

A transistor 10d illustrated in FIG. 5C and FIG. 5D is an example in which the insulating layer 17 is omitted from the above structure of the transistor 10a.

### Variation Example 4

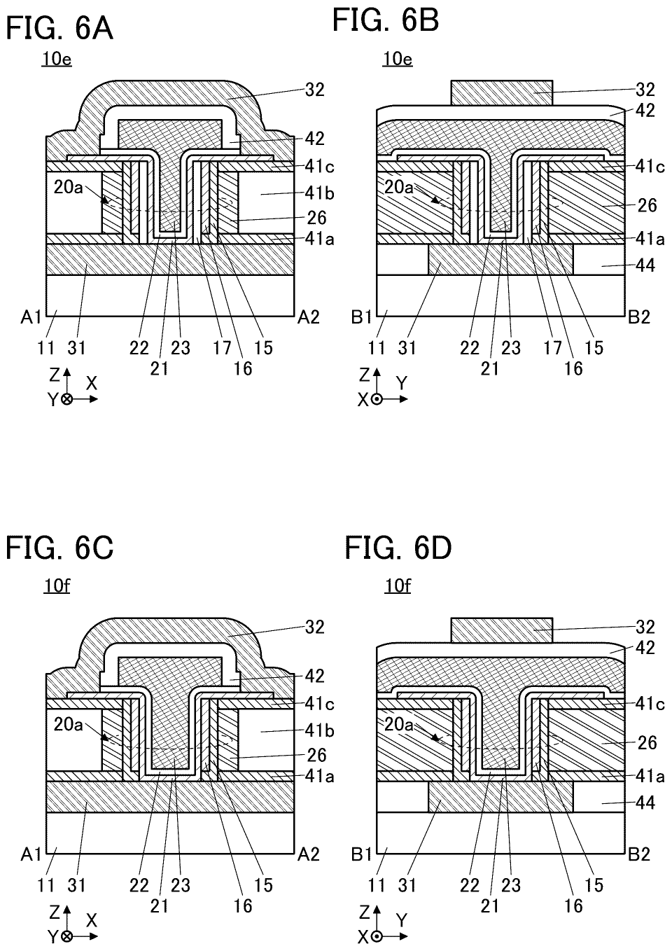

A transistor 10e illustrated in FIG. 6A and FIG. 6B is different from the above transistor 10 mainly in including a conductive layer 26.

The conductive layer 26 is provided in a region surrounded by the insulating layer 41a, the insulating layer 41b, the insulating layer 41c, and the insulating layer 15. It can also be said that the conductive layer 26 is embedded in the insulating layer 41b. The conductive layer 26 is provided to face the semiconductor layer 21 with the insulating layer 15, the insulating layer 16, and the insulating layer 17 therebetween.

The conductive layer 26 serves as a second gate electrode (or a back gate electrode). The insulating layer 15, the insulating layer 16, and the insulating layer 17 are positioned between the conductive layer 26 and the semiconductor layer 21 and serves as a second gate insulating layer (or a back gate insulating layer). A fixed potential or a given signal can be supplied to the conductive layer 26. When the conductive layer 26 is provided and an appropriate potential is supplied to the conductive layer 26, the potential of the semiconductor layer 21 on the back channel side can be fixed, so that a variation in electrical characteristics can be reduced. The conductive layer 26 may be electrically connected to any one of the conductive layer 31, the conductive layer 32, and the conductive layer 23 and supplied with the same potential.

Here, although an example in which the conductive layer 26 extends in the same direction as the extending direction of the conductive layer 23 is illustrated here, one embodiment of the present invention is not limited thereto, and the conductive layer 26 may extend in the same extending direction as the conductive layer 32 or may extend in a direction different from the extending directions of both of the conductive layer 23 and the conductive layer 32.

A transistor 10f illustrated in FIG. 6C and FIG. 6D is an example in which the conductive layer 26 is used as the transistor 10c.

### Variation Example 5

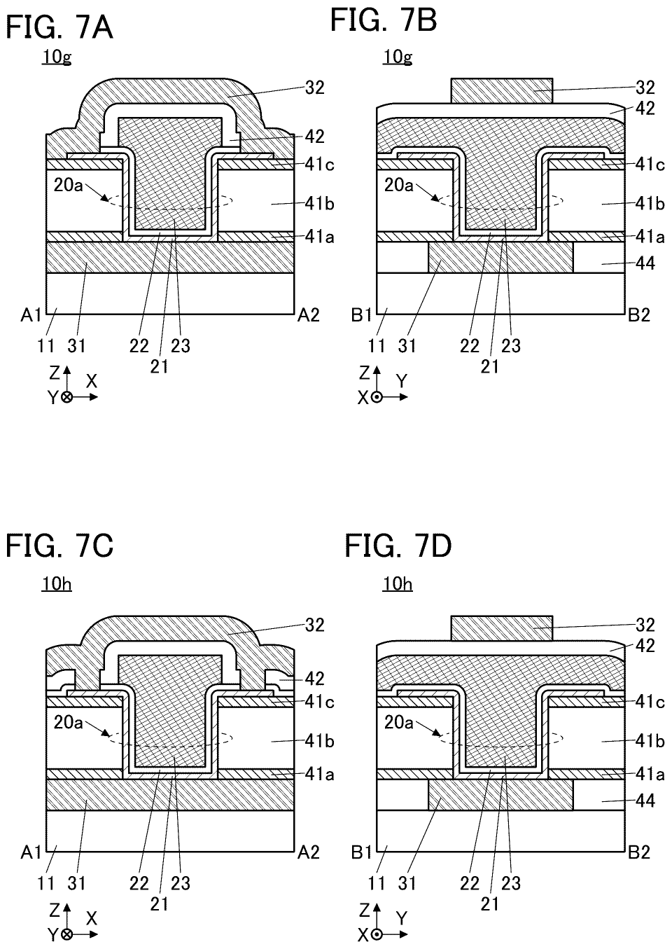

A transistor 10g illustrated in FIG. 7A and FIG. 7B is an example in which the insulating layer 15, the insulating layer 16, and the insulating layer 17 are omitted from the transistor 10.

The semiconductor layer 21 is provided in contact with the inner wall of the opening 20a in the insulating layer 41b. In this case, an oxide insulating film is preferably used for the insulating layer 41b. In particular, an oxide insulating film from which oxygen is released by heating is preferably used. In this case, the insulating layer 41b is sandwiched between the insulating layers 41a and 41c having a barrier property against oxygen; thus, oxygen included in the insulating layer 41b can be enclosed in a region surrounded by the insulating layer 41a, the insulating layer 41c, and the semiconductor layer 21. This can prevent release and reduction of oxygen in the insulating layer 41b in the process, so that oxygen can be supplied to the semiconductor layer 21 more efficiently.

A portion of the semiconductor layer 21 that is in contact with the insulating layer 41b is a region where oxygen vacancies are reduced, i.e., an i-type region. In contrast, the other portion of the semiconductor layer 21 that is not in contact with the insulating layer 41b is preferably an n-type region including a large amount of carriers. That is, the portion of the semiconductor layer 21 that is in contact with the insulating layer 41b can be referred to as a channel formation region and regions outside of the portion can be referred to as low-resistance regions (also referred to as a source region or a drain region).

The insulating layer 41b preferably has a sufficiently low hydrogen concentration. For example, an oxide insulating film deposited by a deposition method that does not include hydrogen as a gas used in deposition is preferably used. It is preferable to use an oxide insulating film formed by a sputtering method, such as silicon oxide or silicon oxynitride. Accordingly, without using the insulating layer 16 having a function of gettering hydrogen, the insulating layer 17 having a hydrogen barrier property, and the like, not only the hydrogen concentration in the semiconductor layer 21 can be reduced but also a large amount of oxygen can be supplied to the semiconductor layer 21; thus, a transistor having high reliability can be achieved.

### Variation Example 6

A transistor 10h illustrated in FIG. 7C and FIG. 7D is different from the transistor 10g mainly in the structures of the insulating layer 42 and the insulating layer 22.

The insulating layer 42 and the insulating layer 22 are provided to cover the semiconductor layer 21 over the insulating layer 41c and the insulating layer 41c, respectively. It can also be said that the insulating layer 22 and the insulating layer 42 are provided to cover an end portion of the semiconductor layer 21. An opening reaching the semiconductor layer 21 is provided in the insulating layer 42 and the insulating layer 22 in a region overlapping with the insulating layer 41c. The conductive layer 32 is electrically connected to the semiconductor layer 21 through the opening.

When the semiconductor layer 21 is covered with the insulating layer 22 and the insulating layer 42 in this manner, impurities can be prevented from diffusing from the exposed portion of the semiconductor layer 21 in the manufacturing process of the transistor; thus, a transistor having high reliability can be achieved.

Note that the structure where the end portion of the semiconductor layer 21 is covered with the insulating layer 22 and/or the insulating layer 42 is not limited to the structure of the transistor 10h and can also be applied to other structure examples. That is, this structure can be used for a structure including at least one of the insulating layer 15, the insulating layer 16, and the insulating layer 17.

### Variation Example 7

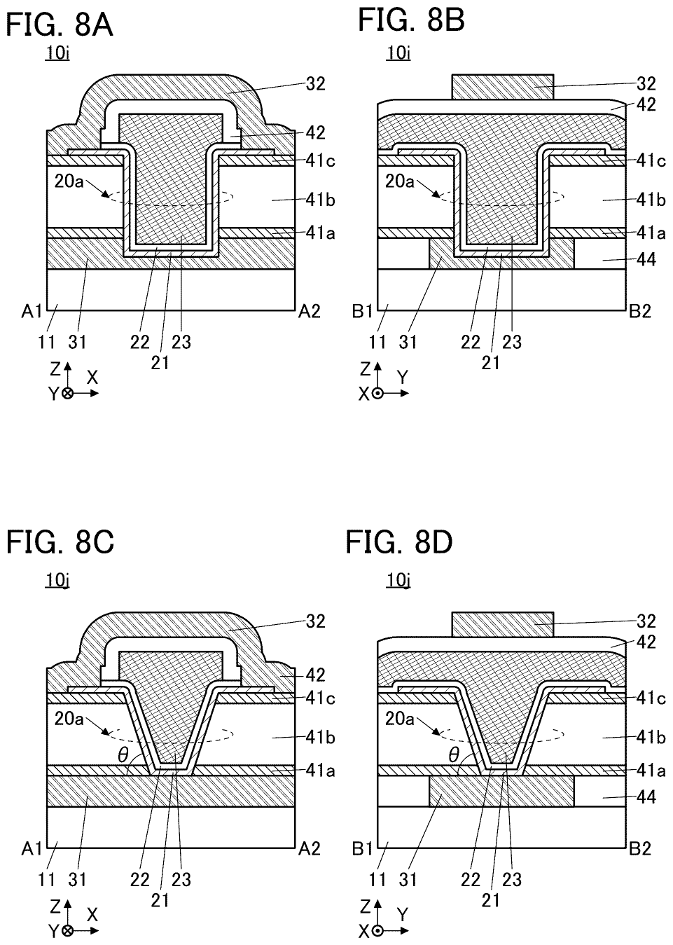

A transistor 10i illustrated in FIG. 8A and FIG. 8B is different from the transistor 10g mainly in the shape of the conductive layer 31.

A concave portion is provided in the conductive layer 31, and the semiconductor layer 21 the insulating layer 22, and the conductive layer 23 are provided along the concave portion. In that case, the level of the lower end of the conductive layer 23 is preferably lower than the level of the top surface of the conductive layer 31.

In the transistor 10i, part of the semiconductor layer 21 that is in contact with the conductive layer 31 is a region having lower resistance than a channel formation region. Thus, when the level of the lower end of the conductive layer 23 is lower than the level of the top surface of the conductive layer 31, a gate electric field can be uniformly applied to the whole channel formation region of the semiconductor layer 21, which prevents formation of a high-resistance region (offset region) due to a poor gate electric field in the semiconductor layer 21. Consequently, a transistor with an increased on-state current can be achieved. To achieve such a structure, for example, the thickness of the conductive layer 31 is preferably made larger than at least the total thicknesses of the semiconductor layer 21 and the insulating layer 22.

Note that the structure of the conductive layer 31 including a concave portion is not limited to the structure of the transistor 10i and can also be applied to other structure examples. That is, this structure can be used for a structure including at least one of the insulating layer 15, the insulating layer 16, and the insulating layer 17.

### Variation Example 8

FIG. 8C and FIG. 8D illustrate a transistor 10j as an example of the case where the opening 20a has a tapered sidewall. In the transistor 10j, the opening 20a has a larger diameter (opening diameter) at an upper end than at a lower end.

The tapered shape of the sidewall of the opening 20a improves the coverage with the semiconductor layer 21, the insulating layer 22, or the like, so that generation of defects such a low-density region in the film can be inhibited even when a deposition method such as a sputtering method is used. The angle θ can be, for example, greater than or equal to 45° and less than or equal to 90°, greater than or equal to 60° and less than 90°, or greater than or equal to 70° and less than 90°. Note that the angle θ may be greater than 90° (i.e., have an inversely tapered shape) when a deposition method achieving an extremely high coverage, such as an ALD method, is used.

In the case where the sidewall of the opening 20a has a tapered shape, the diameter of the opening 20a, which corresponds to the channel width of the transistor 10j, increases from the conductive layer 31 side toward the conductive layer 32 side. The amount of current flowing through the transistor 10j at this time is limited to that of the part with the minimum diameter. Hence, the channel width of the transistor 10j can be regarded as the circumference of the opening with the minimum diameter. Thus, when the sidewall of the opening 20a has a tapered shape, a transistor with a channel width smaller than the diameter of the upper end of the opening 20a can be manufactured.

Note that the structure in which the sidewall of the opening 20a has a tapered shape is not limited to the structure of the transistor 10j and can also be applied to other structure examples. That is, this structure can be used for a structure including at least one of the insulating layer 15, the insulating layer 16, and the insulating layer 17.

The above is the description of the variation examples.

### [Manufacturing Method Example]

Next, a method for manufacturing a semiconductor device of one embodiment of the present invention is described. Here, an example of a method for manufacturing the transistor 10 is described.

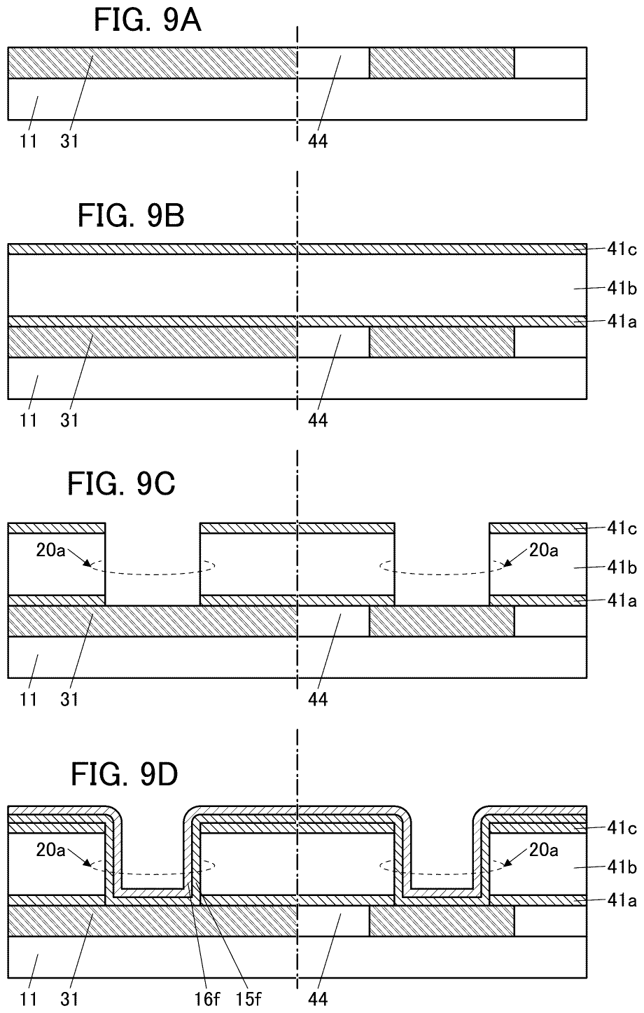

FIG. 9A to FIG. 12C are schematic cross-sectional views of steps in the method for manufacturing a semiconductor device described below as an example. In each drawing, a cross-section corresponding to FIG. 2B is illustrated on the left side, and a cross-section corresponding to FIG. 2C is illustrated on the right side.

Hereinafter, an insulating material for forming an insulating layer, a conductive material for forming a conductive layer, or a semiconductor material for forming a semiconductor layer can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method does not use plasma and thus enables less plasma damage to an object to be processed. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, and the like can be used.

Unlike the sputtering method, the CVD method and the ALD method are less likely to be influenced by the shape of an object to be processed and thus enable favorable step coverage. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors. Furthermore, a film whose composition is continuously changed can be deposited as in the CVD method.

First, a substrate (not illustrated) is prepared, and the insulating layer 11 is formed over the substrate. An inorganic insulating film such as a silicon oxide film or a silicon oxynitride film can be used as the insulating layer 11. The insulating layer 11 can be deposited by a sputtering method, a CVD method, an MBE method, a PLD method, an ALD method, or the like. In the case where the formation surface of the insulating layer 11 is not flat, planarization treatment is preferably performed after the deposition of the insulating layer 11 so that the insulating layer 11 has a flat top surface.

Subsequently, a conductive film to be the conductive layer 31 is formed over the insulating layer 11. After that, a resist mask is formed over the conductive film by a photolithography method or the like, part of the conductive film that is not covered with the resist mask is removed by etching, and then, the resist mask is removed. As a result, the conductive layer 31 can be formed. Next, an insulating film to be the insulating layer 44 is deposited and part thereof that overlaps with the conductive layer 31 is removed, whereby the insulating layer 44 and the conductive layer 31 embedded in the insulating layer 44 can be formed (FIG. 9A). The insulating film to be the insulating layer 44 is preferably processed by a CMP (Chemical Mechanical Polishing) method; for example, the insulating layer 44 illustrated in FIG. 9A can be formed by processing the insulating film until the top surface of the conductive layer 31 is exposed.

Note that the insulating layer 44 and the conductive layer 31 may be formed in the following manner: an insulating film to be the insulating layer 44 is formed first, an opening is formed in the insulating film, a conductive film is formed to fill the opening, and polishing treatment (planarization treatment) using a CMP method is performed until the top surface of the insulating film is exposed.

When the planarization treatment is performed such that the top surfaces of the insulating layer 44 and the conductive layer 31 are level with each other, the sequentially formed insulating layer 41 can have a flat top surface. Note that the insulating layer 44 is not necessarily provided and the insulating layer 41 may be provided to cover the conductive layer 31; in that case, the top surface of the insulating layer 41 is preferably subjected to planarization treatment by a CMP method so as to have a flat top surface.

Then, the insulating layer 41a, the insulating layer 41b, and the insulating layer 41c (hereinafter collectively referred to as the insulating layer 41 in some cases) are formed over the conductive layer 31 and the insulating layer 44 (FIG. 9B). The insulating layer 41a, the insulating layer 41b, and the insulating layer 41c can be formed by a sputtering method, a CVD method, an MBE method, a PLD method, an ALD method, or the like as appropriate.

Here, the thickness of the insulating layer 41 affects the channel length of the transistor; thus, it is important to prevent a variation in the thickness of the insulating layer 41.

In the case where the insulating layer 41b is in contact with the semiconductor layer 21, when the insulating layer 41b is deposited by a sputtering method in an oxygen-including atmosphere, the insulating layer 41b including a large amount of oxygen therein can be formed. By using a sputtering method that does not need to use a molecule including hydrogen in a deposition gas, the hydrogen concentration in the insulating layer 41b can be reduced. When the insulating layer 41b is deposited in this manner, oxygen can be supplied from the insulating layer 41b to the channel formation region of the semiconductor layer 21, so that oxygen vacancies can be reduced.

Then, the opening 20a reaching the conductive layer 31 is formed in the insulating layer 41 (FIG. 9C).

The sidewall of the opening 20a is preferably as perpendicular as possible to the top surface of the conductive layer 31. This structure allows the transistor with a small occupation area to be manufactured. The sidewall of the opening 20a may have a tapered shape. The tapered shape improves the coverage with a film formed in the opening 20a.

The maximum width of the opening 20a (the maximum diameter in the case where the opening 20a is circular in the plan view) is preferably as small as possible. For example, the maximum width of the opening 20a is preferably less than or equal to 2 μm, 1 μm, less than or equal to 500 nm, less than or equal to 300 nm, less than or equal to 150 nm, less than or equal to 100 nm, less than or equal to 60 nm, less than or equal to 50 nm, less than or equal to 40 nm, less than or equal to 30 nm, or less than or equal to 20 nm and greater than or equal to 5 nm. In particular, in order to process the opening 20a finely, a lithography method using an electron beam or short-wavelength light such as EUV light is preferably used.

The opening 20a is preferably formed by anisotropic etching. Processing by a dry etching method is particularly preferable because it is suitable for fine processing. The insulating layer 41c, the insulating layer 41b, and the insulating layer 41a may be processed under different etching conditions. Note that the sidewall angle of the opening 20a may be different in the insulating layer 41c, the insulating layer 41b, and the insulating layer 41a.

The upper part of the conductive layer 31 is partly etched in some cases when the insulating layer 41 is etched, so that the thickness of the conductive layer 31 at the bottom part of the opening 20a is reduced. Alternatively, the thickness of the conductive layer 31 may be reduced by partly etching the upper part of the conductive layer 31 after the formation of the opening 20a.

Heat treatment may be performed after that. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere including an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, after heat treatment is performed in a nitrogen gas or inert gas atmosphere, the heat treatment may be performed in an atmosphere including an oxidizing gas at 10 ppm or more, 1% or more, or 10% or more in order to compensate for oxygen released. The heat treatment described above allows impurities such as water or hydrogen included in the insulating layer 41 or the like to be reduced before deposition of an oxide semiconductor film to be the semiconductor layer.

The gas used in the above-described heat treatment is preferably highly purified. For example, the amount of moisture included in the gas used in the above-described heat treatment is less than or equal to 1 ppb, preferably less than or equal to 0.1 ppb, and further preferably less than or equal to 0.05 ppb. The heat treatment using a highly purified gas can prevent entry of moisture or the like into the insulating layer 41 or the like as much as possible.

Next, an insulating film 15f and an insulating film 16f are formed to cover the insulating layer 41c, the opening 20a, the conductive layer 31, and the like (FIG. 9D). The insulating film 15f is a film to be the insulating layer 15 later, and the insulating film 16f is a film to be the insulating layer 16 later.

For the insulating film 15f and the insulating film 16f, a sputtering method, a CVD method, an MBE method, a PLD method, an ALD method, or the like can be used as appropriate. It is particularly preferable to form the insulating film 15f and the insulating film 16f by an ALD method with high coverage. The insulating film 15f and the insulating film 16f are preferably formed by the same deposition method, further preferably successively formed without exposure to the air. Specifically, the insulating film 15f and the insulating film 16f are preferably successively formed in vacuum with an ALD apparatus.

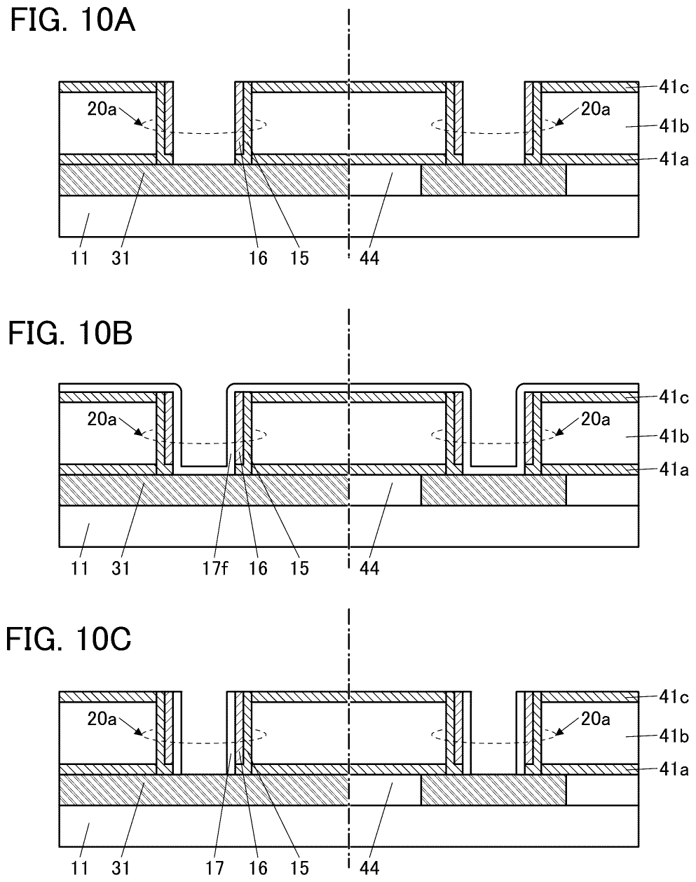

Next, the insulating film 15f and the insulating film 16f are subjected to anisotropic etching so that the top surfaces of the insulating layer 41c and the conductive layer 31 are exposed, whereby the insulating layer 15 and the insulating layer 16 can be formed inside the opening 20a (FIG. 10A).

Next, an insulating film 17f is formed to cover the insulating layer 41c, the opening 20a, the insulating layer 15, the insulating layer 16, the conductive layer 31, and the like (FIG. 10B). The insulating film 17f is a film to be the insulating layer 17 later.

The insulating film 17f can be formed by a deposition method similar to that for the insulating film 15f and the insulating film 16f.

During or after the deposition of the insulating film 17f, treatment for supplying oxygen to the insulating film 17f may be performed. Examples include heat treatment in an oxygen atmosphere and plasma treatment in an oxygen atmosphere.

Next, the insulating film 17f is subjected to anisotropic etching so that the top surfaces of the insulating layer 41c and the conductive layer 31 are exposed, whereby the insulating layer 17 can be formed inside the opening 20a (FIG. 10C).

Then, heat treatment may be performed to reduce impurities such as water and hydrogen included in the insulating layer 17 or the like. For the heat treatment method, the above description can be referred to.

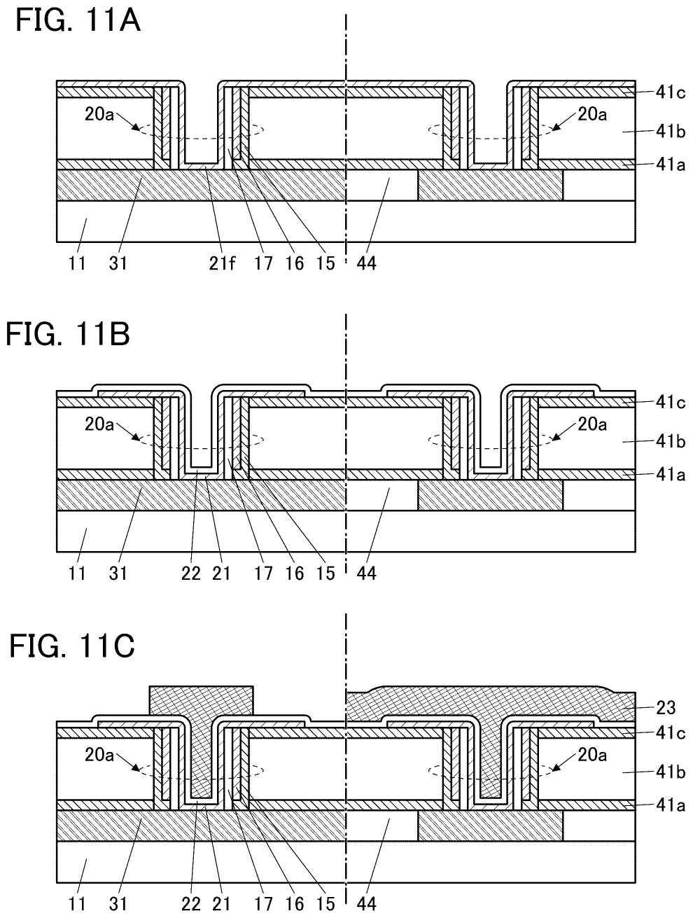

Next, a semiconductor film 21f to be the semiconductor layer 21 is deposited to cover the insulating layer 41, the conductive layer 31, the opening 20a, the insulating layer 15, the insulating layer 16, the insulating layer 17, and the like (FIG. 11A). After that, an unnecessary portion of the semiconductor film 21f is removed by etching to form the semiconductor layer 21.

An oxide semiconductor film can be used as the semiconductor film 21f. The oxide semiconductor film may be deposited as appropriate by a sputtering method, a CVD method, an MBE method, a PLD method, an ALD method, or the like. Here, the oxide semiconductor film is preferably formed in contact with the bottom part and sidewall of the opening 20a with a high aspect ratio. Thus, the oxide semiconductor film is preferably deposited by a deposition method enabling favorable coverage, and is further preferably formed by a CVD method, an ALD method, or the like. For example, In—Ga—Zn oxide is deposited by an ALD method as the oxide semiconductor film. In the case where the opening 20a has a tapered shape, the oxide semiconductor film can be deposited by a sputtering method.

During or after the deposition of the oxide semiconductor film, microwave treatment is preferably performed in an oxygen-including atmosphere so that the impurity concentration in the oxide semiconductor film can be reduced. Specific examples of the impurity include hydrogen and carbon. The microwave treatment can increase the crystallinity of the oxide semiconductor film in some cases. Here, the microwave treatment refers to, for example, treatment using an apparatus including a power source that generates high-density plasma with use of a microwave.

The microwave treatment in an oxygen-including atmosphere converts an oxygen gas into plasma using a high-frequency wave such as a microwave or RF and activates the oxygen plasma. The oxygen that works on the oxide semiconductor has any of a variety of forms such as an oxygen atom, an oxygen molecule, an oxygen ion, and an oxygen radical (also referred to as O radical, which is an atom, a molecule, or an ion having an unpaired electron). Note that the oxygen that works on the oxide semiconductor may have any one or more of the above forms; an oxygen radical is particularly preferable.

The aforementioned microwave treatment in an oxygen-including atmosphere is preferably performed while the substrate is heated, in which case the impurity concentration in the oxide semiconductor can be further reduced. The substrate heating temperature is higher than or equal to 100° C. and lower than or equal to 650° C., preferably higher than or equal to 200° C. and lower than or equal to 600° C., further preferably higher than or equal to 300° C. and lower than or equal to 450° C.

When the microwave treatment in an oxygen-including atmosphere is performed while the substrate is heated, the carbon concentration in the oxide semiconductor film, which is measured by SIMS, can be lower than 1×10²⁰ atoms/cm³, preferably lower than 1×10¹⁹ atoms/cm³, further preferably lower than 1×10¹⁸ atoms/cm³.

The above-described example in which the microwave treatment in an oxygen-including atmosphere is performed on the oxide semiconductor film is a non-limiting example. For example, the microwave treatment in an oxygen-including atmosphere may be performed on an insulating film, specifically a silicon oxide film, which is positioned in the vicinity of the oxide semiconductor film. This allows hydrogen included in the silicon oxide film to be released as H₂O to the outside. Release of hydrogen from the silicon oxide film positioned in the vicinity of the oxide semiconductor film can offer a highly reliable semiconductor device. For example, microwave treatment may be performed on the insulating layer 22 to be formed later in an oxygen-including atmosphere.

In the case where the semiconductor layer 21 has a stacked-layer structure, the layers may be deposited by the same method or different methods from each other. For example, in the case where the semiconductor layer 21 has a stacked-layer structure of two layers, the lower oxide semiconductor film may be deposited by a sputtering method and the upper oxide semiconductor film may be deposited by an ALD method. An oxide semiconductor film deposited by a sputtering method is likely to have crystallinity. Thus, when an oxide semiconductor film having crystallinity is provided as the lower oxide semiconductor film, the crystallinity of the upper oxide semiconductor film can be increased. Even when a pinhole, disconnection, or the like is formed in the lower oxide semiconductor film deposited by a sputtering method, a portion overlapping with the pinhole, disconnection, or the like can be filled with the upper oxide semiconductor film deposited by an ALD method enabling favorable coverage.

After the deposition of the oxide semiconductor film, heat treatment is preferably performed. The heat treatment is performed in a temperature range where the oxide semiconductor film does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere including an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, after heat treatment is performed in a nitrogen gas or inert gas atmosphere, the heat treatment may be performed in an atmosphere including an oxidizing gas at 10 ppm or more, 1% or more, or 10% or more in order to compensate for oxygen released.

The gas used in the above-described heat treatment is preferably highly purified. For example, the amount of moisture included in the gas used in the above-described heat treatment is less than or equal to 1 ppb, preferably less than or equal to 0.1 ppb, and further preferably less than or equal to 0.05 ppb. The heat treatment using a highly purified gas can prevent entry of moisture or the like into the oxide semiconductor film or the like as much as possible.

Here, the above-described heat treatment is preferably performed in the state where the semiconductor film is in contact with the insulating layer 17 including a large amount of oxygen. In that case, oxygen is supplied from the insulating layer 17 to the portion of the semiconductor film that is to be the channel formation region, whereby oxygen vacancies can be reduced.

Although the heat treatment is performed after the deposition of the oxide semiconductor film in the above description, the present invention is not limited thereto. Heat treatment may be performed in a later step.

Next, an insulating layer 22 is formed to cover the semiconductor layer 21 and the insulating layer 41c (FIG. 11B). The insulating layer 22 can be deposited by a sputtering method, a CVD method, an MBE method, a PLD method, an ALD method, or the like.

The insulating layer 22 is preferably provided to have a thickness as uniform as possible on the side surface of the semiconductor layer 21 in the opening 20a. Thus, the insulating layer 22 is particularly preferably formed by an ALD method, which is a deposition method enabling extremely excellent coverage. Note that in the case where the opening 20a has a sidewall with a tapered shape, the insulating layer 22 can be deposited by a deposition method such as a sputtering method.

Next, a conductive film is deposited to cover the insulating layer 22 and to be embedded in the opening 20a, and an unnecessary portion is removed by etching, so that the conductive layer 23 is formed (FIG. 11C). In that case, the conductive layer 23 is formed so that the width in the direction orthogonal to the extending direction is smaller than the width of the semiconductor layer 21. That is, a portion not covered with the conductive layer 23 is formed in the semiconductor layer 21.

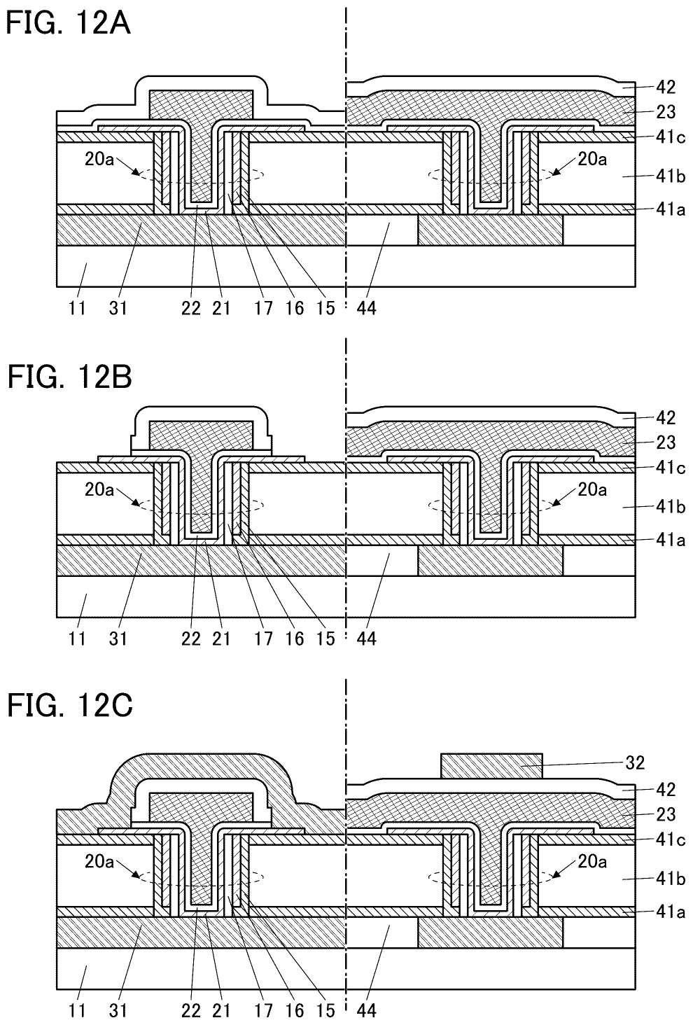

Next, the insulating layer 42 is formed to cover the insulating layer 22 and the conductive layer 23 (FIG. 12A). The insulating layer 42 is preferably formed using a material having a lower permittivity than at least the insulating layer 22. The insulating layer 42 is preferably formed to be at least thicker than the insulating layer 22. For example, the insulating layer 22 can be formed by a deposition method such as a sputtering method or a plasma CVD method.

Next, part of the insulating layer 42 and part of the insulating layer 22 are removed by etching to expose part of the top surface of the semiconductor layer 21 (FIG. 12B). At this time, the insulating layer 42 is etched in a region where the conductive layer 23 is not provided so that the conductive layer 23 is enclosed by the insulating layer 42 and the insulating layer 22.

Note that FIG. 12B illustrates an example in which the insulating layer 44 and the insulating layer 22 are etched so that the end portion of the semiconductor layer 21 is exposed; however, one embodiment of the present invention is not limited thereto, and the insulating layer 22 and the insulating layer 44 can be etched so that the end portion of the semiconductor layer 21 is covered with the insulating layer 22 and the insulating layer 44. In that case, the insulating layer 41c is not exposed and is covered with the insulating layer 22.

Next, a conductive film is deposited over the insulating layer 42, the semiconductor layer 21, and the like and then, an unnecessary portion is removed by etching, so that the conductive layer 32 is formed (FIG. 12C). The conductive layer 32 includes a portion in contact with the semiconductor layer 21 in a region not overlapping with the conductive layer 23.

Through the above process, the transistor 10 can be manufactured.

With the manufacturing method in one embodiment of the present invention, the hydrogen concentration in the channel formation region can be effectively reduced, so that the transistor can have high reliability. In addition, a thick interlayer insulating layer can be provided between the gate electrode and the upper electrode; thus, parasitic capacitance therebetween can be reduced and a transistor that can be used in a circuit required to operate at high speed can be achieved.

The above is the description of the manufacturing method example.

### [Application Example]

A structure of a memory device including a transistor and a capacitor is described below.

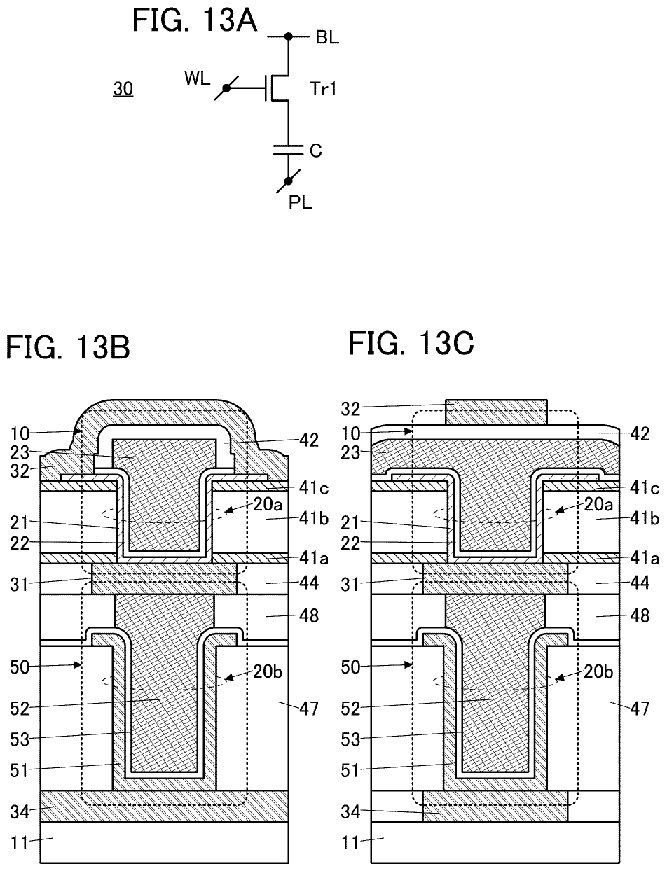

FIG. 13A is a circuit diagram of a memory cell 30. The memory cell 30 includes one transistor Tr1 and one capacitor C and is also referred to as 1Tr1C. Agate of the transistor Tr1 is connected to a wiring WL, one of a source and a drain of the transistor Tr1 is connected to a wiring BL, and the other thereof is connected to one electrode of the capacitor C. The other electrode of the capacitor C is connected to a wiring PL.

In the memory cell 30, a data potential input from the wiring BL through the transistor Tr1 is retained in the capacitor C, whereby data can be stored. When the transistor Tr1 is brought into a non-conduction state, the data can be retained. When the transistor Tr is brought into a conduction state, a potential corresponding to the retained data is output to the wiring BL, which allows data reading. A signal for controlling the conduction or non-conduction of the transistor Tr1 is supplied to the wiring WL. A predetermined potential (e.g., a fixed potential) is supplied to the wiring PL.

FIG. 13B and FIG. 13C are cross-sectional views of the memory cell 30. FIG. 13B is a cross-sectional view along the extending direction of the conductive layer 32 and the conductive layer 34, and FIG. 13C is a cross-sectional view along the extending direction of the conductive layer 23. The memory cell 30 has a structure in which the transistor 10 is stacked over the capacitor 50. The transistor 10 and the capacitor 50 correspond to the transistor Tr1 and the capacitor C, respectively.

Description of the structure of the transistor 10 is omitted because the above description can be referred to. Note that the example of using the transistor 10 shown here is a non-limiting example, and the transistor 10 can be replaced with any of the variety of transistors described above.

The capacitor 50 includes a conductive layer 51, a conductive layer 52, and an insulating layer 53 sandwiched therebetween. The capacitor 50 forms what is called a MIM (Metal-Insulator-Metal) capacitor.

The capacitor 50 is provided over the insulating layer 11. A conductive layer 34 is provided over the insulating layer 11, and the insulating layer 47 is provided over the conductive layer 34. In the insulating layer 47, an opening 20b reaching the conductive layer 34 is provided. In the opening 20b, the conductive layer 51 is provided in contact with the side surface of the insulating layer 47 and the top surface of the conductive layer 34. The insulating layer 53 is provided to cover the insulating layer 47 and the conductive layer 51. An insulating layer 48 is provided over the insulating layer 53. The conductive layer 52 is provided to be embedded in the insulating layer 48 and the opening 20b.

The top surfaces of the conductive layer 52 and the insulating layer 48 are planarized and substantially level with each other. The insulating layer 44 and the conductive layer 31 are provided over the conductive layer 52 and the insulating layer 48. The conductive layer 31 is provided in contact with the top surface of the conductive layer 52.

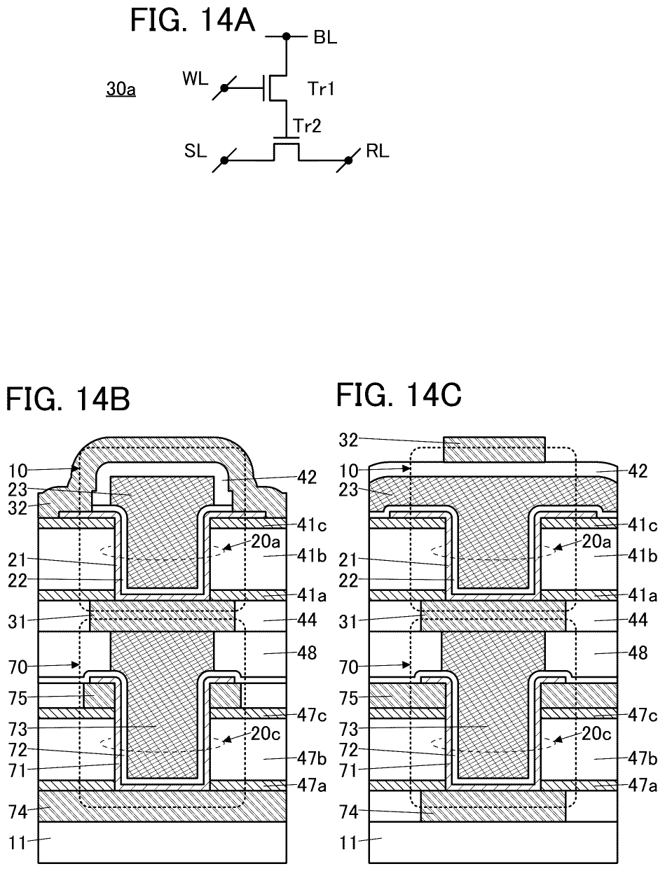

In FIG. 14B and FIG. 14C, the conductive layer 32 corresponds to the wiring BL, the conductive layer 23 corresponds to the wiring WL, and the conductive layer 34 corresponds to the wiring PL.

A low-resistance conductive material can be used for the conductive layer 34, the conductive layer 51, and the conductive layer 52. For example, any of the materials that can be used for the conductive layer 23 can be used.

The insulating layer 53 serves as a dielectric layer of the capacitor 50. The capacitance of the capacitor 50 can be increased as the insulating layer 53 has a smaller thickness and a higher relative dielectric constant. For example, a high-k material that can be used for the insulating layer 22 is preferably used.

FIG. 14A illustrates a circuit diagram of a memory cell 30a. The memory cell 30a has a structure in which the capacitor C of the memory cell 30 is replaced with a transistor Tr2. In the transistor Tr2, a gate is connected to the other of the source and the drain of the transistor Tr1, one of a source and a drain is connected to a wiring SL, and the other is connected to a wiring RL.

The memory cell 30a can store data when a data potential input from the wiring BL through the transistor Tr1 is retained at a node to which the gate of the transistor Tr2 is connected. The data can be retained when the transistor Tr1 is brought into a non-conduction state. The electrical continuity between the wiring SL and the wiring RL changes depending on a potential retained in the gate of the transistor Tr2. For example, a signal can be supplied to one of the wiring SL and the wiring RL, and data can be read on the basis of the magnitude of a potential or current output to the other of the wiring SL and the wiring RL. Thus, the memory cell 30a can be used as a non-destructive readable memory.

Note that the capacitor C may be provided in the memory cell 30a illustrated in FIG. 14A. More specifically, one electrode of the capacitor C can be connected to a node to which the other of the source and the drain of the transistor Tr1 and the gate of the transistor Tr2 are connected. In this case, the wiring PL can be connected to the other electrode of the capacitor C. The capacitor C may have a structure similar to that of the above-described capacitor 50, or can employ any of a variety of MIM capacitors such as a parallel plate capacitor, a cylinder capacitor, and a pillar capacitor.

FIG. 14B and FIG. 14C are cross-sectional views of the memory cell 30a. The memory cell 30a has a structure in which the transistor 10 is stacked over a transistor 70. The structure of the transistor 10 is similar to that of the memory cell 30.

The transistor 70 includes a conductive layer 74, a semiconductor layer 71, an insulating layer 72, a conductive layer 73, a conductive layer 75, and the like. The transistor 70 is a vertical transistor provided in a region overlapping with the opening 20c provided in the conductive layer 75, an insulating layer 47a, an insulating layer 47b, and an insulating layer 47c. The transistor 70 is different from the transistor 10 mainly in the structure of the upper electrode, and the description of the transistor 10 can be referred to for other common components.

The conductive layer 74 is provided over the insulating layer 11, and the insulating layer 47a, the insulating layer 47b, and the insulating layer 47c are stacked over the conductive layer 74. The conductive layer 75 is provided over the insulating layer 47c. The semiconductor layer 71 and the insulating layer 72 are provided along an inner wall of the opening 20c provided in the conductive layer 75, the insulating layer 47a, the insulating layer 47b, and the insulating layer 47c. The semiconductor layer 71 is provided in contact with the top surface and the side surface of the conductive layer 75, the side surfaces of the insulating layer 47a, the insulating layer 47b, and the insulating layer 47c, and the top surface of the conductive layer 74. The conductive layer 73 is provided to fill the insulating layer 48 and the opening 20c.

In FIG. 14B and FIG. 14C, the conductive layer 31 and the conductive layer 73 correspond to the gate of the transistor Tr2, the conductive layer 75 corresponds to one of the wiring SL and the wiring RL, and the conductive layer 74 corresponds to the other of the wiring SL and the wiring RL.

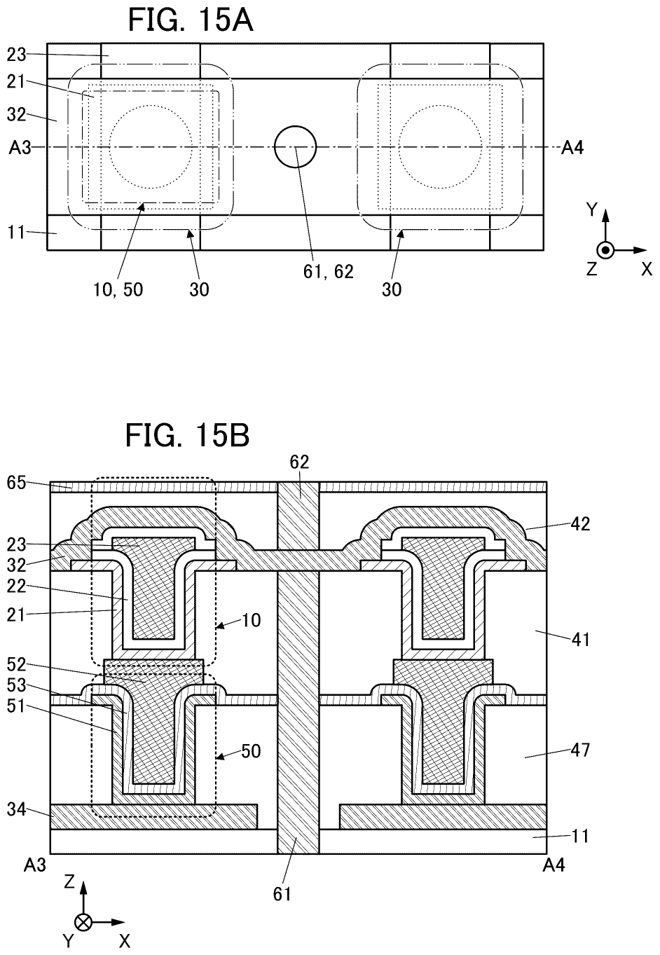

FIG. 15A and FIG. 15B illustrate an example of a memory device in which two memory cells 30 are connected to a common wiring. FIG. 15A is a schematic top view of the memory device, and FIG. 15B is a schematic cross-sectional view along the cutting line A3-A4 in FIG. 15A.

The conductive layer 23 serving as the wiring WL is provided in each of the two memory cells 30. The conductive layer 32 serving as the wiring BL is provided to be shared by the two memory cells 30.

The conductive layer 32 serving as the wiring BL is embedded in an interlayer insulating layer and electrically connected to a conductive layer 61 and a conductive layer 62 serving as plugs (also referred to as connection electrodes). The conductive layer 61 may be configured to be electrically connected to a sense amplifier (not illustrated) provided below the insulating layer 11. The conductive layer 61 may be configured to be electrically connected to the conductive layer 32 of a memory cell stacked above an insulating layer 65.

The insulating layer 65 serves as a barrier layer and has a function of preventing diffusion of impurities such as water and hydrogen from the outside into the memory device.

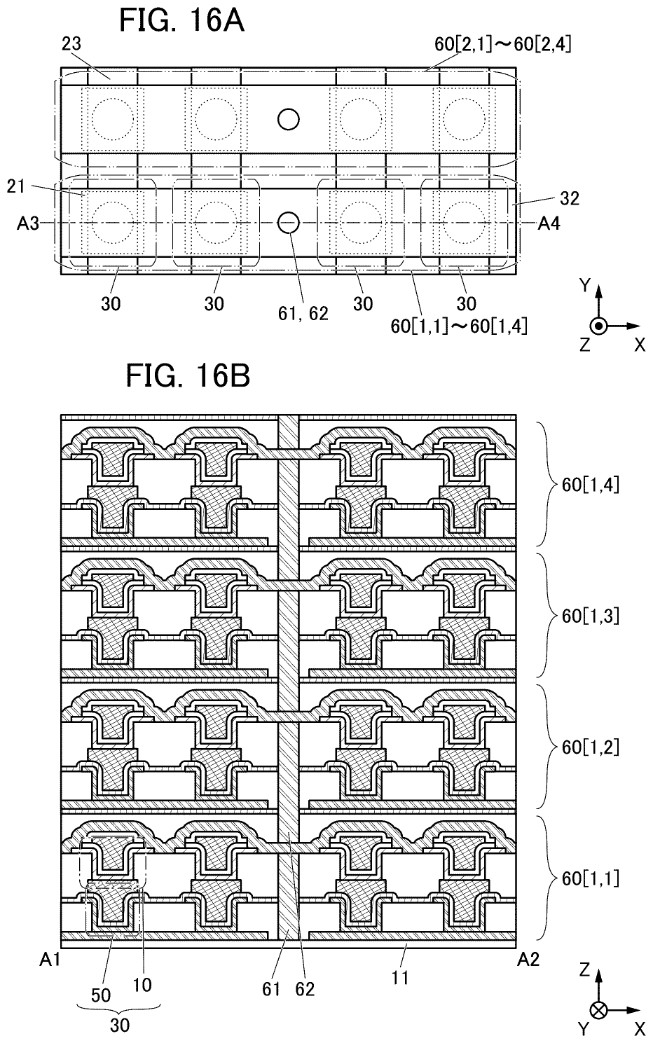

The memory cells 30 may be three-dimensionally arranged in a matrix to form a memory cell array. As an example of the memory cell array, FIG. 16A and FIG. 16B illustrate an example of a memory device in which 4×2×4 memory cells 30 are arranged in the X direction, the Y direction, and the Z direction. FIG. 16A is a plan view of the memory device, and FIG. 16B is a cross-sectional view taken along the cutting line A3-A4 in FIG. 16A.

A group consisting of four memory cells 30 can be referred to as a memory unit 60. FIG. 16A and FIG. 16B illustrate eight memory units (a memory unit 60[1,1] to a memory unit 60[2,4]). In the memory unit 60[a,b] (a and b are each a positive integer), a represents an address in the Y direction and b represents an address in the Z direction.

In the memory unit 60, two memory cells 30 are arranged symmetrically with the conductive layer 61 or the conductive layer 62 as the center. The conductive layer 62 electrically connects the conductive layers 32 of the memory units 60 stacked in the Z direction. When a plurality of memory units 60 are stacked in this manner, storage capacity per unit area can be increased, and a memory device that can be miniaturized or highly integrated can be provided.

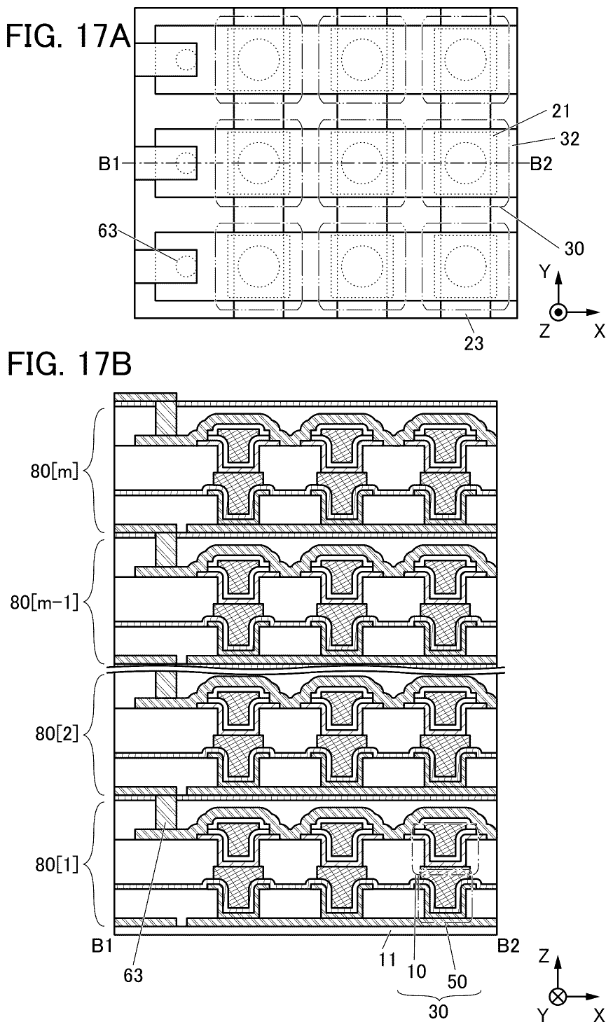

FIG. 17A and FIG. 17B illustrate an example in which a connection portion is placed at an end of the memory unit. FIG. 17A is a plan view of the memory device, and FIG. 17B is a cross-sectional view thereof. Shown here is an example of the memory device in which 3×3×m (m is an integer greater than or equal to 2) memory cells 30 are arranged as an example of a memory cell array. Among layers including the memory cells 30, a first layer and an m-th (uppermost) layer are denoted by a layer 80[1] and a layer 80[m], respectively.

A conductive layer 63 is provided outside the memory unit. The conductive layer 63 may be connected to a wiring in a layer above the layer 80 including the conductive layer 63. For example, the conductive layer 63 provided in the layer 80[1] is electrically connected to a wiring provided in a layer 80[2]. Note that without limitation thereto, the conductive layer 63 may be configured to be electrically connected to a wiring in the layer 80 positioned below the layer 80 including the conductive layer 63 itself.

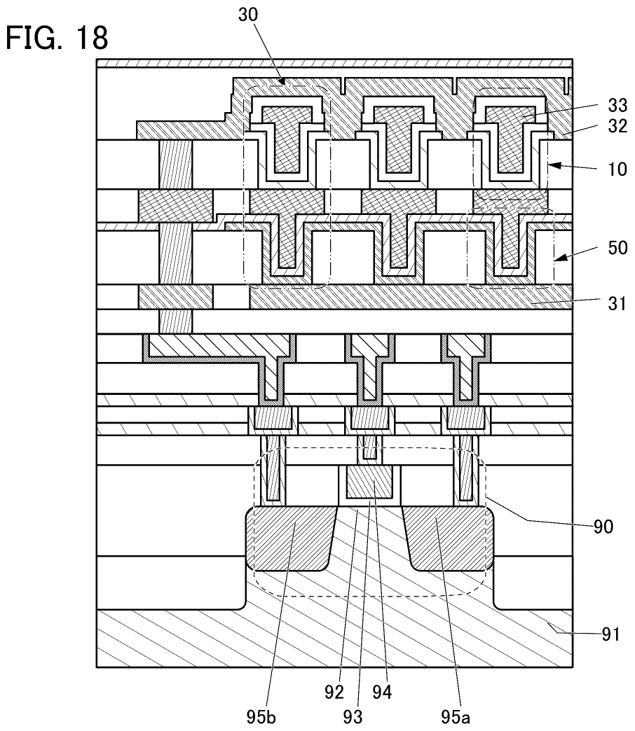

FIG. 18 illustrates a cross-sectional structure example of a memory device in which a layer including the memory cells 30 is stacked over a layer where a driver circuit including a sense amplifier is provided.

FIG. 18 illustrates an example in which the capacitor 50 is stacked over a transistor 90 and the transistor 10 is stacked thereover. The transistor 90 is one of the transistors included in the sense amplifier.

With the structure in which the sense amplifier is provided to overlap with the memory cell 30, a bit line can be shortened. Accordingly, the load on the bit line is reduced, which can improve the read sensitivity in the sense amplifier. Thus, the storage capacitance of the memory cell can be reduced.

The transistor 90 is provided on a substrate 91 and includes a conductive layer 94 serving as a gate, an insulating layer 93 serving as a gate insulating layer, a semiconductor region 92 formed of part of the substrate 91, and a low-resistance region 95a and a low-resistance region 95b serving as a source region and a drain region. The transistor 90 may be either a p-channel transistor or an n-channel transistor.

Here, in the transistor 90 illustrated in FIG. 18, the semiconductor region 92 (part of the substrate 91) where a channel is formed has a protruding shape. The conductive layer 94 is provided to cover the side surface and the top surface of the semiconductor region 92 with the insulating layer 93 therebetween. Such a transistor 90 is also referred to as a FIN-type transistor because it utilizes the protruding portion of the semiconductor substrate.

A structure in which an interlayer insulating layer and a wiring layer are alternately stacked (also referred to as a multilayer wiring layer) is preferably provided between a layer including the transistor 90 and a layer including the memory cell 30. FIG. 18 illustrates an example in which the low-resistance region 95b of the transistor 90 is electrically connected to the conductive layer 32 serving as a bit line of the memory cell 30 through a wiring and a plug.

At least part of this embodiment can be implemented in combination with the other embodiments described in this specification as appropriate.

### Embodiment 2

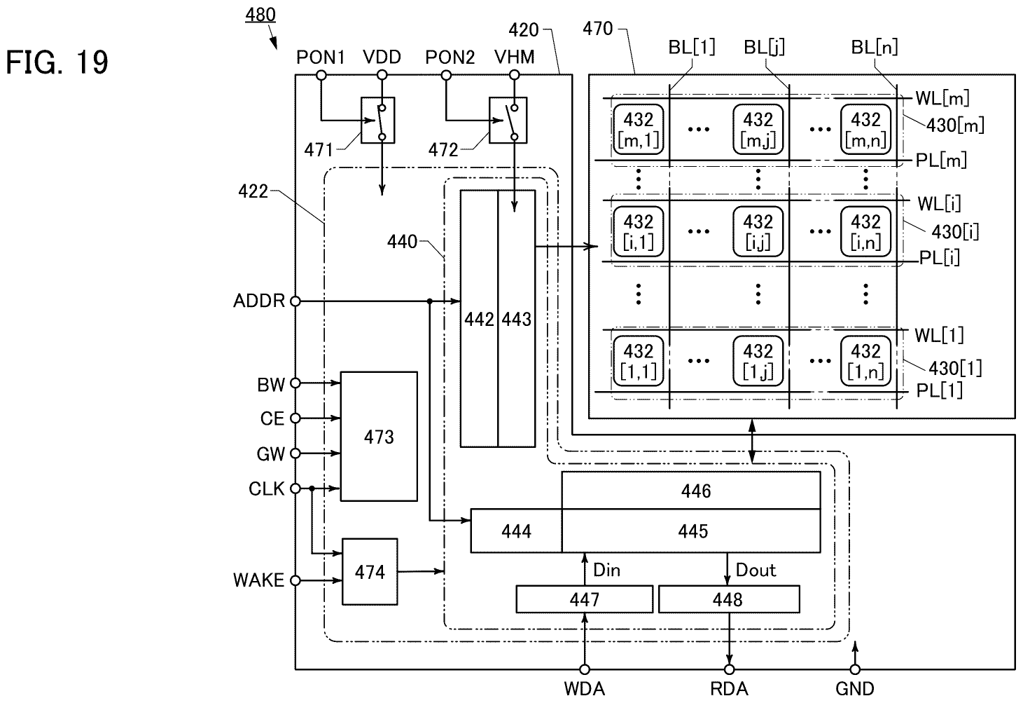

In this embodiment, a memory device of one embodiment of the present invention will be described with reference to FIG. 19 to FIG. 22. A structure example of a memory device in which a layer including memory cells is provided to be stacked over a layer provided with a driver circuit including a sense amplifier will be described in this embodiment.

### <Structure Example of Memory Device>

FIG. 19 is a block diagram illustrating a structure example of a memory device 480 according to one embodiment of the present invention. The memory device 480 illustrated in FIG. 19 includes a layer 420 and a layer 470 stacked thereover.

The layer 420 is a layer including Si transistors. The layer 470 is provided with element layers 430[1] to 430[m] (m is an integer greater than or equal to 2) as stacked layers. The element layers 430[1] to 430[m] are layers each including an OS transistor. The layer 470 provided with the stacked layers each including the OS transistor can be provided to be stacked over the layer 420.

Elements such as OS transistors and capacitors included in the element layers 430[1] to 430[m] form memory cells. FIG. 19 illustrates an example in which the element layers 430[1] to 430[m] include a plurality of memory cells 432 arranged in a matrix of m rows and n columns (n is an integer greater than or equal to 2).

In FIG. 19, the memory cell 432 in the first row and the first column is denoted as a memory cell 432[1,1], and the memory cell 432 in the m-th row and the n-th column is denoted as a memory cell 432[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 432 in the i-th row and the j-th column is denoted as a memory cell 432[i,j]. Note that in this embodiment and the like, “i+α” (α is a positive or negative integer) is not below 1 and does not exceed m. Similarly, “j+α” is not below 1 and does not exceed n.

FIG. 19 illustrates, as an example, m wirings WL extending in a row direction, m wirings PL extending in the row direction, and n wirings BL extending in a column direction. In this embodiment and the like, the first (first row) wiring WL is denoted as a wiring WL[1] and the m-th (m-th row) wiring WL is denoted as a wiring WL[m]. Similarly, the first (first row) wiring PL is denoted as a wiring PL[1] and the m-th (m-th row) wiring PL is denoted as a wiring PL[m]. Similarly, the first (first column) wiring BL is denoted as a wiring BL[1] and the n-th (n-th column) wiring BL is denoted as a wiring BL[n]. Note that the number of the element layers 430[1] to 430[m] is not necessarily the same as the number of the wirings WL (and the wirings PL).

The plurality of memory cells 432 provided in the i-th row are electrically connected to the wiring WL in the i-th row (wiring WL[i]) and the wiring PL in the i-th row (wiring PL[i]). The plurality of memory cells 432 provided in the j-th column are electrically connected to the wiring BL in the j-th column (wiring BL[j]).

The wiring BL serves as a bit line for writing and reading data. The wiring WL serves as a word line for controlling on or off (a conduction state or a non-conduction state) of an access transistor serving as a switch. The wiring PL has a function of a constant potential line connected to a capacitor. Note that a wiring for transmitting a back gate potential can be additionally provided.

The memory cells 432 included in each of the element layers 430[1] to 430[m] are connected to a sense amplifier 446 through the wiring BL. The wiring BL can be provided horizontally and perpendicularly to the surface of the substrate where the layer 420 is provided. When the wiring BL extending from the memory cells 432 included in the element layers 430[1] to 430[m] is formed using a wiring provided perpendicularly to the substrate surface as well as a wiring provided horizontally to the substrate surface, the length of the wiring between the element layers 430 and the sense amplifier 446 can be shortened. The signal transmission distance between the memory cell and the sense amplifier can be shortened and the resistance and parasitic capacitance of the bit line can be significantly reduced, so that power consumption and signal delay can be reduced. Thus, power consumption and signal delay of the memory device 480 can be reduced. Moreover, operation is possible even when the capacitance of the capacitors included in the memory cells 432 is reduced. Thus, the memory device 480 can be downsized.

The layer 420 includes a PSW 471 (power switch), a PSW 472, and a peripheral circuit 422. The peripheral circuit 422 includes a driver circuit 440, a control circuit 473, and a voltage generation circuit 474. Note that each circuit included in the layer 420 is a circuit including a Si transistor.

In the memory device 480, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 473.

The control circuit 473 is a logic circuit having a function of controlling the entire operation of the memory device 480. For example, the control circuit performs logical operation on the signal CE, the signal GW, and the signal BW to determine an operation mode (e.g., write operation or read operation) of the memory device 480. Alternatively, the control circuit 473 generates a control signal for the driver circuit 440 so that the operation mode is executed.

The voltage generation circuit 474 has a function of generating negative voltage. The signal WAKE has a function of controlling the input of the signal CLK to the voltage generation circuit 474. For example, when an H-level signal is supplied as the signal WAKE, the signal CLK is input to the voltage generation circuit 474, and the voltage generation circuit 474 generates negative voltage.

The driver circuit 440 is a circuit for writing and reading data to/from the memory cells 432. The driver circuit 440 includes the above-described sense amplifier 446 in addition to a row decoder 442, a column decoder 444, a row driver 443, a column driver 445, an input circuit 447 (Input Cir.), and an output circuit 448 (Output Cir.).

The row decoder 442 and the column decoder 444 have a function of decoding the signal ADDR. The row decoder 442 is a circuit for specifying a row to be accessed, and the column decoder 444 is a circuit for specifying a column to be accessed. The row driver 443 has a function of selecting the wiring WL specified by the row decoder 442. The column driver 445 has a function of writing data to the memory cells 432, a function of reading data from the memory cells 432, a function of retaining the read data, and the like.

The input circuit 447 has a function of retaining the signal WDA. Data retained by the input circuit 447 is output to the column driver 445. Data output from the input circuit 447 is data (Din) to be written to the memory cells 432. Data (Dout) read from the memory cells 432 by the column driver 445 is output to the output circuit 448. The output circuit 448 has a function of retaining Dout. In addition, the output circuit 448 has a function of outputting Dout to the outside of the memory device 480. Data output from the output circuit 448 is the signal RDA.

The PSW 471 has a function of controlling the supply of VDD to the peripheral circuit 422. The PSW 472 has a function of controlling the supply of VHM to the row driver 443. Here, in the memory device 480, high power supply voltage is VDD and low power supply voltage is GND (a ground potential). In addition, VHM is high power supply voltage used to set the word line at a high level and is higher than VDD. The on/off of the PSW 471 is controlled by the signal PON1, and the on/off of the PSW 472 is controlled by the signal PON2. The number of power domains to which VDD is supplied is one in the peripheral circuit 422 in FIG. 19 but can be more than one. In that case, a power switch is provided for each power domain.

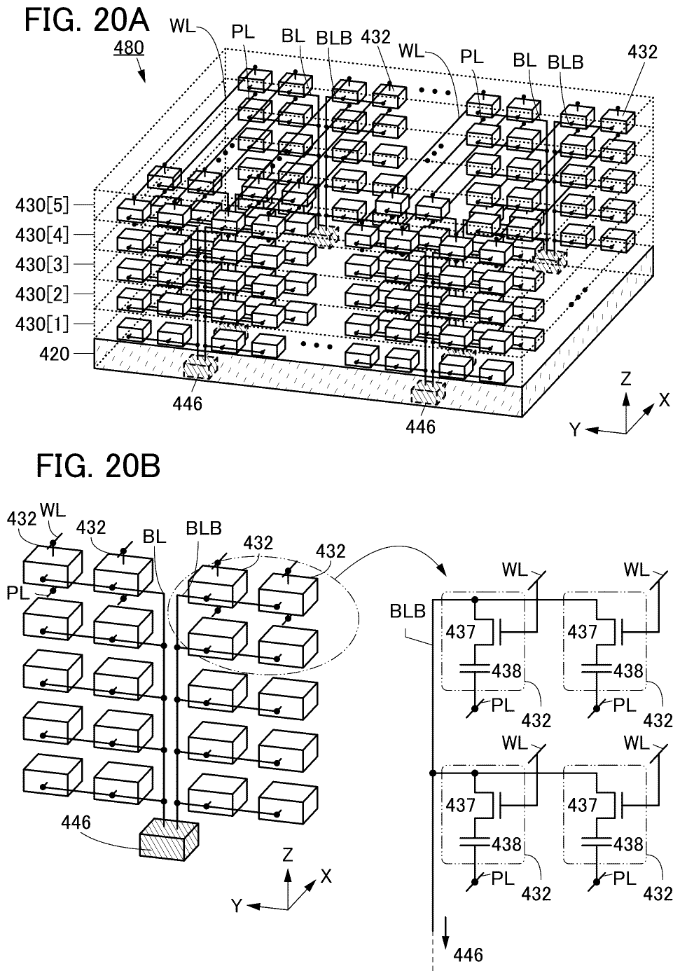

The element layers 430[1] to 430[m] can be provided over the layer 420 to overlap with the layer 420. FIG. 20A illustrates a perspective view of the memory device 480 in which five (m=5) element layers 430[1] to 430[5] are provided over the layer 420 to overlap with the layer 420.

In FIG. 20A, the element layer 430 provided in the first layer is denoted as the element layer 430[1], the element layer 430 provided in the second layer is denoted as the element layer 430[2], and the element layer 430 provided in the fifth layer is denoted as the element layer 430[5]. FIG. 20A also illustrates the wiring WL and the wiring PL provided to extend in the X direction and the wiring BL and a wiring BLB provided to extend in the Y direction and the Z direction (the direction perpendicular to the surface of the substrate where the driver circuit is provided). The wiring BLB is an inverted bit line. Note that for easy viewing of the drawing, some of the wirings WL and the wirings PL included in the element layers 430 are not illustrated.

FIG. 20B illustrates a schematic view illustrating a structure example of the sense amplifier 446, which is connected to the wiring BL and the wiring BLB, and the memory cells 432 included in the element layers 430[1] to 430[5], which are connected to the wiring BL and the wiring BLB, illustrated in FIG. 20A. Note that a structure where a plurality of memory cells (memory cells 432) are electrically connected to one wiring BL and one wiring BLB is also referred to as a “memory string.”

FIG. 20B illustrates an example of a circuit structure of the memory cell 432 connected to the wiring BLB. The memory cell 432 includes a transistor 437 and a capacitor 438. As for the transistor 437, the capacitor 438, and the wirings (BL, WL, and the like), for example, the wiring BL[1] and the wiring WL[1] are referred to as the wiring BL and the wiring WL in some cases. The memory cell 30 illustrated as an example in the above embodiment can be used as the memory cell 432, for example. In other words, the transistor 10 can be used as the transistor 437, and the capacitor 50 can be used as the capacitor 438. As the transistor included in the sense amplifier 446, the transistor 90 (see FIG. 18) can be used.

In the memory cell 432, one of a source and a drain of the transistor 437 is connected to the wiring BL. The other of the source and the drain of the transistor 437 is connected to one electrode of the capacitor 438. The other electrode of the capacitor 438 is connected to the wiring PL. A gate of the transistor 437 is connected to the wiring WL.

The wiring PL is a wiring for supplying a constant potential for retaining the potential of the capacitor 438. When a plurality of wirings PL are connected to each other and used as one wiring, the number of wirings can be reduced.

In one embodiment of the present invention, OS transistors are provided to be stacked and a wiring serving as a bit line is provided in the direction perpendicular to the surface of the substrate where the layer 420 is provided. In addition, the transistors 437 and the capacitors 438 included in the memory cells 432 are arranged in the direction perpendicular to the surface of the substrate where the layer 420 is provided. When the elements and the wirings are provided in the direction perpendicular to the substrate surface, the length of the wiring between the element layers can be shortened and the density of the elements per unit area can be increased. Thus, the memory device can have excellent memory capacity and be excellent in reducing power consumption.

### [Structure Examples of Memory Cell 432 and Sense Amplifier 446]

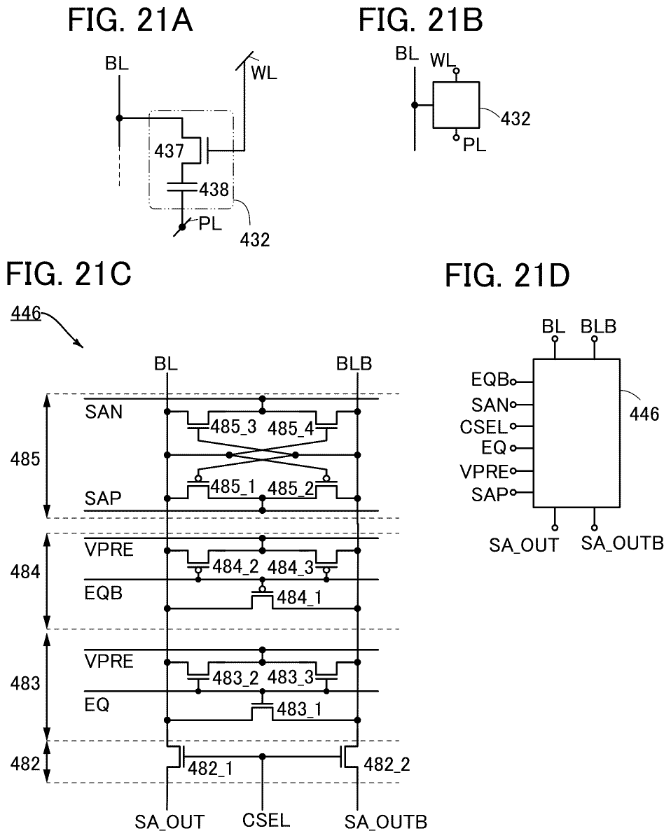

FIG. 21A and FIG. 21B illustrate a circuit diagram corresponding to the above-described memory cell 432 and a circuit block diagram corresponding to the circuit diagram. As illustrated in FIG. 21A and FIG. 21B, the memory cell 432 is illustrated as a block in the drawing and the like in some cases. Note that the same can be applied to the case where the wiring BL illustrated in FIG. 21A and FIG. 21B is replaced with the wiring BLB.

FIG. 21C and FIG. 21D illustrate a circuit diagram corresponding to the above-described sense amplifier 446 and a circuit block diagram corresponding to the circuit diagram. As the sense amplifier 446, a switch circuit 482, a precharge circuit 483, a precharge circuit 484, and an amplifier circuit 485 are illustrated. In addition to the wiring BL and the wiring BLB, a wiring SA_OUT and a wiring SA_OUTB that output a read signal are illustrated.

The switch circuit 482 includes, for example, n-channel transistors 482_1 and 482_2, as illustrated in FIG. 21C. The transistors 482_1 and 482_2 switch a conduction state between a wiring pair of the wiring SA_OUT and the wiring SA_OUTB and a wiring pair of the wiring BL and the wiring BLB in response to a signal CSEL.

The precharge circuit 483 includes n-channel transistors 483_1 to 483_3, as illustrated in FIG. 21C. The precharge circuit 483 is a circuit for precharging the wiring BL and the wiring BLB with an intermediate potential VPRE corresponding to a potential VDD/2 in response to a signal EQ.

The precharge circuit 484 includes p-channel transistors 484_1 to 484_3, as illustrated in FIG. 21C. The precharge circuit 484 is a circuit for precharging the wiring BL and the wiring BLB with the intermediate potential VPRE corresponding to the potential VDD/2 in response to a signal EQB.

The amplifier circuit 485 includes p-channel transistors 485_1 and 485_2 and n-channel transistors 485_3 and 485_4 that are connected to a wiring SAP or a wiring SAN, as illustrated in FIG. 21C. The wiring SAP or the wiring SAN is a wiring having a function of supplying VDD or VSS. The transistors 485_1 to 485_4 are transistors that form an inverter loop.

FIG. 21D illustrates a circuit block diagram corresponding to the sense amplifier 446 described with reference to FIG. 21C or the like. As illustrated in FIG. 21D, the sense amplifier 446 is illustrated as a block in the drawing and the like in some cases.

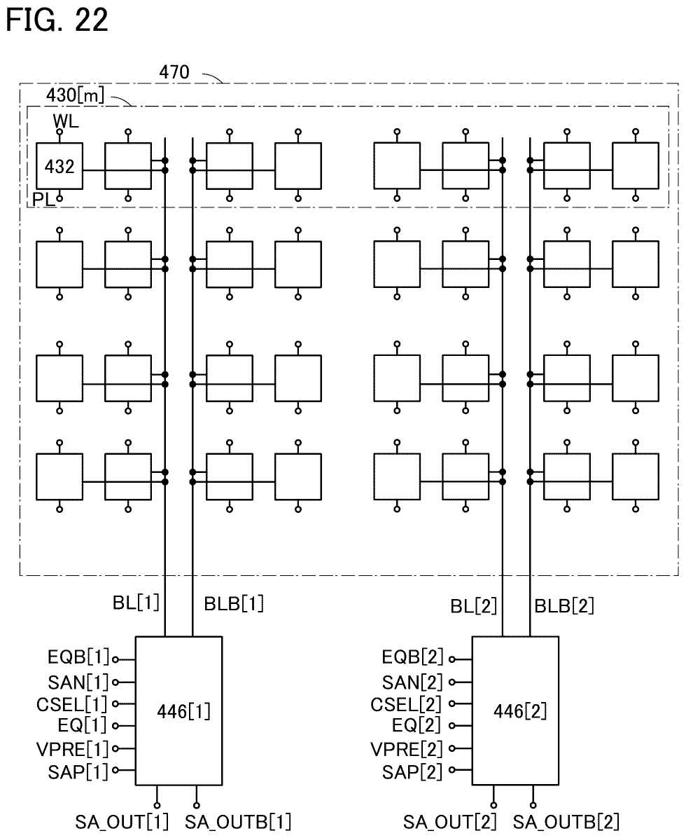

FIG. 22 is a circuit diagram of the memory device 480 in FIG. 19. In the illustration in FIG. 22, the circuit blocks illustrated in FIG. 21A to FIG. 21D are used.

As illustrated in FIG. 22, the layer 470 including the element layer 430[m] includes the memory cells 432. The memory cells 432 illustrated in FIG. 22 are connected to a pair of the wiring BL[1] and a wiring BLB[1], or a pair of a wiring BL[2] and a wiring BLB[2], for example. The memory cells 432 connected to the wiring BL are memory cells to/from which data is written or read.

The wiring BL[1] and the wiring BLB[1] are connected to a sense amplifier 446[1], and the wiring BL[2] and the wiring BLB[2] are connected to a sense amplifier 446[2]. The sense amplifier 446[1] and the sense amplifier 446[2] can perform data reading in accordance with the various signals described with reference to FIG. 21C.

At least part of this embodiment can be implemented in combination with the other embodiments described in this specification as appropriate.

### Embodiment 3

In this embodiment, structure examples of a display device that can employ the transistor of one embodiment of the present invention will be described.

Since the transistor of one embodiment of the present invention can be extremely minute, a display device that employs the transistor of one embodiment of the present invention can be an extremely high-resolution display device. For example, a display device of one embodiment of the present invention can be used for display portions of information terminal devices (wearable devices) such as wristwatch-type and bracelet-type information terminal devices and display portions of devices that can be worn on a head, such as VR devices like head-mounted displays (HMDs) and glasses-type AR devices.

### [Display Module]

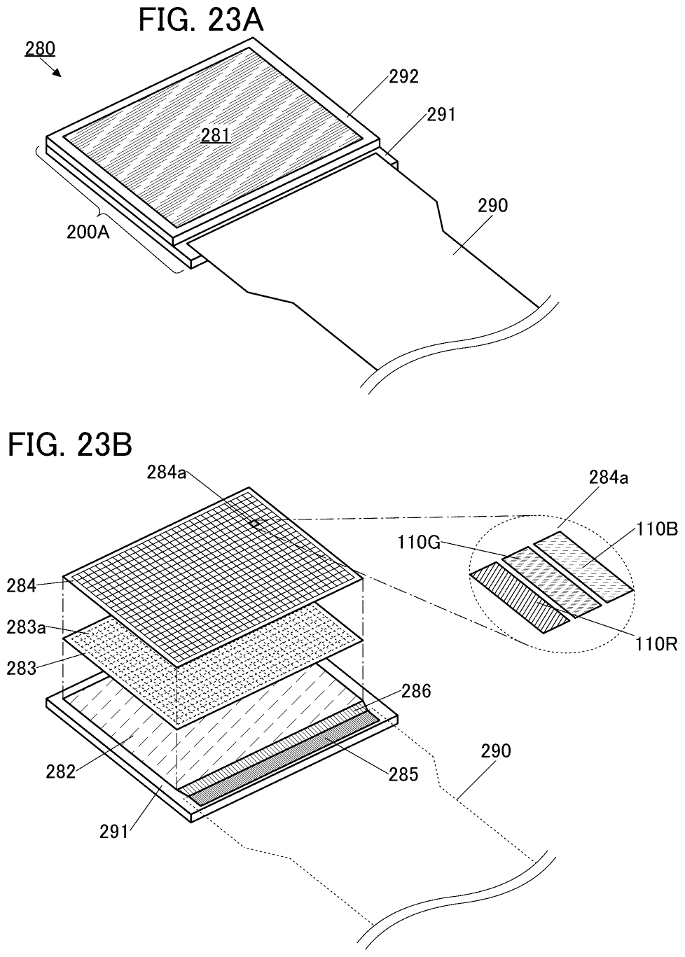

FIG. 23A is a perspective view of a display module 280. The display module 280 includes a display device 200A and an FPC 290. Note that a display panel included in the display module 280 is not limited to the display device 200A and may be either a display device 200B or a display device 200C described later.

The display module 280 includes a substrate 291 and a substrate 292. The display module 280 includes a display portion 281. The display portion 281 is a region where an image is displayed.

FIG. 23B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. In addition, a terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 23B. The pixel 284a includes a light-emitting element 110R that emits red light, a light-emitting element 110G that emits green light, and a light-emitting element 110B that emits blue light.

The pixel circuit portion 283 includes a plurality of pixel circuits 283a arranged periodically. One pixel circuit 283a is a circuit for controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may further include at least one of an arithmetic circuit, a memory circuit, a power supply circuit, and the like. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 serves as a wiring for supplying a video signal, a power supply potential, and the like to the circuit portion 282 from the outside. In addition, an IC may be mounted on the FPC 290.

The display module 280 can have a structure in which one or both of the pixel circuit portion 283 and the circuit portion 282 are provided to be stacked below the pixel portion 284; thus, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even in the case of a structure in which the display portion of the display module 280 is seen through a lens, pixels of the extremely-high-resolution display portion 281 included in the display module 280 are not seen even when the display portion is enlarged by the lens, so that display providing a high sense of immersion can be performed. Without being limited thereto, the display module 280 can be also suitably used for an electronic appliance having a comparatively small display portion. For example, the display module 280 can be suitably used for a display portion of a wearable electronic appliance, such as a wristwatch.

### [Display Device 200A]

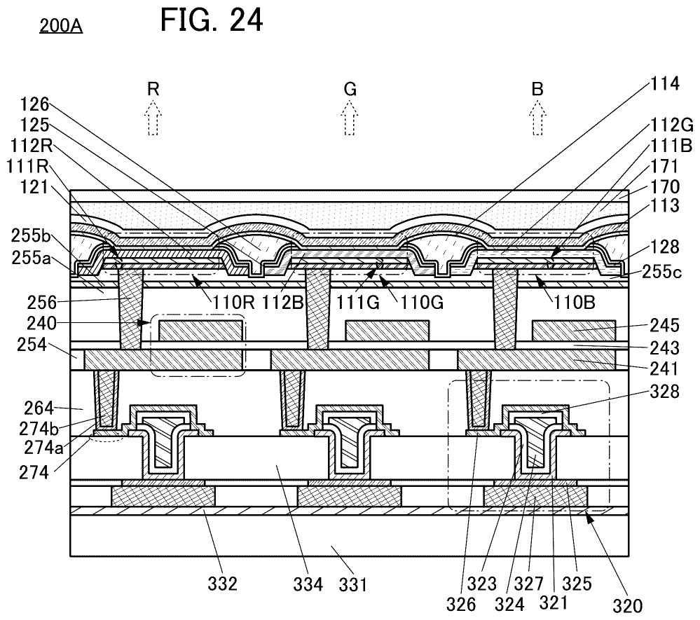

The display device 200A illustrated in FIG. 24 includes a substrate 331, the light-emitting element 110R, the light-emitting element 110G, the light-emitting element 110B, a capacitor 240, and a transistor 320.

The substrate 331 corresponds to the substrate 291 in FIG. 23A.

The transistor 320 is a vertical-channel transistor in which an oxide semiconductor is employed in a semiconductor layer where a channel is formed. The transistor 320 includes a semiconductor layer 321, an insulating layer 323, a conductive layer 324, a conductive layer 325, a conductive layer 326, and the like.

As the transistor 320, a variety of transistors shown as examples in Embodiment 1 can be employed.

An insulating layer 332 is provided over the substrate 331. The insulating layer 332 serves as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

A conductive layer 327 is provided over the insulating layer 332, and the conductive layer 325 is provided over the conductive layer 327. In addition, an insulating layer 334 is provided over the conductive layer 325, and the conductive layer 326 is provided over the insulating layer 334. An opening is provided in the insulating layer 334, and the semiconductor layer 321 and the insulating layer 323 are provided in the opening. The conductive layer 324 is provided over the insulating layer 323, and the insulating layer 328 is provided to cover the top surface and the side surface of the conductive layer 324. The conductive layer 326 is provided over the insulating layer 328 and the semiconductor layer 321. An insulating layer 264 is provided to cover the conductive layer 326.

The insulating layer 264 serves as an interlayer insulating layer. A barrier layer that prevents diffusion of impurities such as water and hydrogen from the insulating layer 264 or the like into the transistor 320 may be provided between the insulating layer 264 and an insulating layer 254. For the barrier layer, an insulating film similar to the insulating layer 332 can be used.

A plug 274 electrically connected to one of the conductive layers 326 is provided to be embedded in the insulating layer 264. Here, the plug 274 preferably includes a conductive layer 274a that covers side surface of opening in the insulating layer 264, and part of the top surface of the conductive layer 326, and a conductive layer 274b in contact with the top surface of the conductive layer 274a. In that case, a conductive material in which hydrogen and oxygen are less likely to diffuse is preferably used for the conductive layer 274a.

The capacitor 240 is provided over the insulating layer 264. The capacitor 240 includes a conductive layer 241, a conductive layer 245, and an insulating layer 243 positioned therebetween. The conductive layer 241 serves as one electrode of the capacitor 240, the conductive layer 245 serves as the other electrode of the capacitor 240, and the insulating layer 243 serves as a dielectric of the capacitor 240.

The conductive layer 241 is provided over the insulating layer 264 and is embedded in an insulating layer 254. The conductive layer 241 is electrically connected to the conductive layer 326 of the transistor 320 through the plug 274. The insulating layer 243 is provided to cover the conductive layer 241. The conductive layer 245 is provided in a region overlapping the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to serve as an etching protective film. Although this embodiment shows an example in which the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c.

The light-emitting element 110R includes the pixel electrode 111R, the organic layer 112R, the common layer 114, and the common electrode 113. The light-emitting element 110G includes the pixel electrode 111G, the organic layer 112G, the common layer 114, and the common electrode 113. The light-emitting element 110B includes the pixel electrode 111B, the organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R includes at least a light-emitting organic compound that emits red light. The organic layer 112G included in the light-emitting element 110G includes at least a light-emitting organic compound that emits green light. The organic layer 112B included in the light-emitting element 110B includes at least a light-emitting organic compound that emits blue light. Each of the organic layer 112R, the organic layer 112G, and the organic layer 112B can also be referred to as an EL layer and includes at least a layer including a light-emitting organic compound (a light-emitting layer).

In the display device 200A, since the light-emitting devices of different colors are separately formed, a change in chromaticity between light emission at low luminance and light emission at high luminance is small. Furthermore, since the organic layers 112R, 112G, and 112B are separated from each other, crosstalk generated between adjacent subpixels can be inhibited while the display panel has high resolution. It is thus possible to achieve a display panel that has high resolution and high display quality.

In a region between adjacent light-emitting elements, an insulating layer 125, a resin layer 126, and a layer 128 are provided.

The pixel electrode 111R, the pixel electrode 111G, and the pixel electrode 111B of the light-emitting elements are each electrically connected to the conductive layer 326 of the transistor 320 through a plug 256 that is embedded in the insulating layer 255a, the insulating layer 255b, and the insulating layer 255c, the conductive layer 241 that is embedded in the insulating layer 254, and the plug 274. The top surface of the insulating layer 255c and the top surface of the plug 256 are level with or substantially level with each other. A variety of conductive materials can be used for the plugs.

A protective layer 121 is provided over the light-emitting elements 110R, 110G, and 110B. A substrate 170 is attached onto the protective layer 121 with an adhesive layer 171.

An insulating layer covering an end portion of the top surface of the pixel electrode 111 is not provided between two adjacent pixel electrodes 111. Thus, the distance between adjacent light-emitting elements can be extremely narrowed. Accordingly, the display device can have high resolution or high definition.

### [Display Device 200B]

A display device whose structure is partly different from the above structure will be described below. Note that the above description is referred to for portions common to those described above and the description thereof is omitted in some cases.

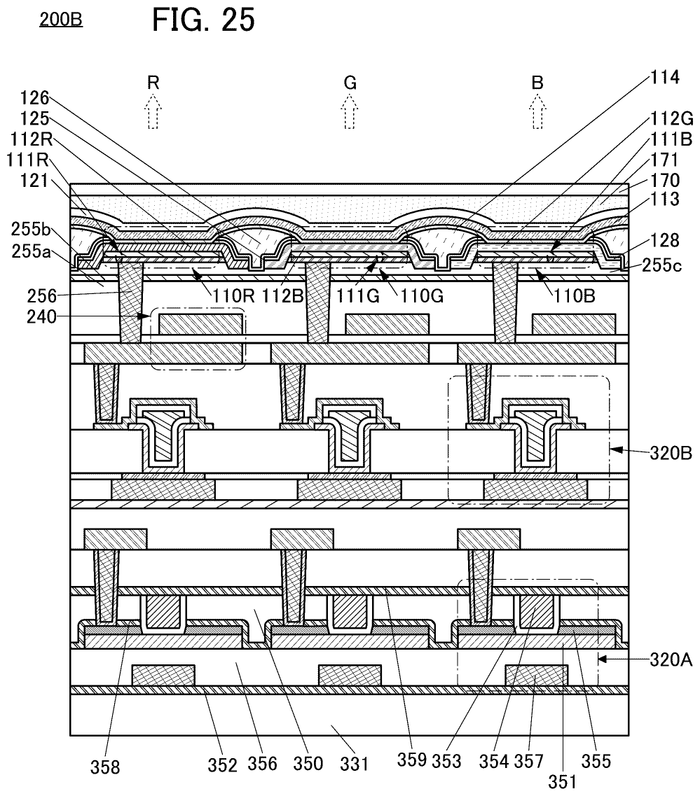

The display device 200B illustrated in FIG. 25 is an example in which a transistor 320A, which is a planar transistor including a semiconductor layer formed on a plane, and a transistor 320B, which is a vertical-channel transistor, are stacked. The transistor 320B has a structure similar to that of the transistor 320 in the display device 200A.

The transistor 320A includes a semiconductor layer 351, an insulating layer 353, a conductive layer 354, a pair of conductive layers 355, an insulating layer 356, and a conductive layer 357.

The insulating layer 352 is provided over the substrate 331. The insulating layer 352 serves as a barrier layer that prevents diffusion of impurities such as water and hydrogen from the substrate 331 into the transistor 320 and release of oxygen from the semiconductor layer 351 to the insulating layer 352 side. As the insulating layer 352, for example, a film in which hydrogen or oxygen is less likely to diffuse than in a silicon oxide film, such as an aluminum oxide film, a hafnium oxide film, or a silicon nitride film, can be used.

The conductive layer 357 is provided over the insulating layer 352, and the insulating layer 356 is provided to cover the conductive layer 357. The conductive layer 357 serves as a first gate electrode of the transistor 320A, and part of the insulating layer 356 serves as a first gate insulating layer. An oxide insulating film such as a silicon oxide film is preferably used for at least part of the insulating layer 356 that is in contact with the semiconductor layer 351. The top surface of the insulating layer 356 is preferably planarized.

The semiconductor layer 351 is provided over the insulating layer 356. The semiconductor layer 351 preferably includes a metal oxide (also referred to as an oxide semiconductor) film exhibiting semiconductor characteristics. The pair of conductive layers 355 is provided on and in contact with the semiconductor layer 351, and serves as a source electrode and a drain electrode.

An insulating layer 358 and an insulating layer 350 are provided to cover top surfaces and side surfaces of the pair of conductive layers 355, side surfaces of the semiconductor layer 351, and the like. The insulating layer 358 serves as a barrier layer that prevents diffusion of impurities such as water and hydrogen into the semiconductor layer 351 and release of oxygen from the semiconductor layer 351. As the insulating layer 358, an insulating film similar to the insulating layer 352 can be used.

An opening reaching the semiconductor layer 351 is provided in the insulating layer 358 and the insulating layer 350. The conductive layer 354 and the insulating layer 353 that is in contact with the top surface of the semiconductor layer 351 are embedded in the opening. The conductive layer 354 serves as a second gate electrode, and the insulating layer 353 serves as a second gate insulating layer.

The top surface of the conductive layer 354, the top surface of the insulating layer 353, and the top surface of the insulating layer 350 are subjected to planarization treatment so that they are level with or substantially level with each other, and an insulating layer 359 is provided to cover these layers. The insulating layer 359 serves as a barrier layer that prevents diffusion of impurities such as water and hydrogen into the transistor 320. For the insulating layer 359, an insulating film similar to the insulating layer 352 can be used.

A structure in which the semiconductor layer where a channel is formed is sandwiched between two gates is employed for the transistor 320. The two gates may be connected to each other and supplied with the same signal to drive the transistor. Alternatively, a potential for controlling the threshold voltage may be applied to one of the two gates and a potential for driving may be applied to the other of the two gates to control the threshold voltage of the transistor.

### [Display Device 200C]

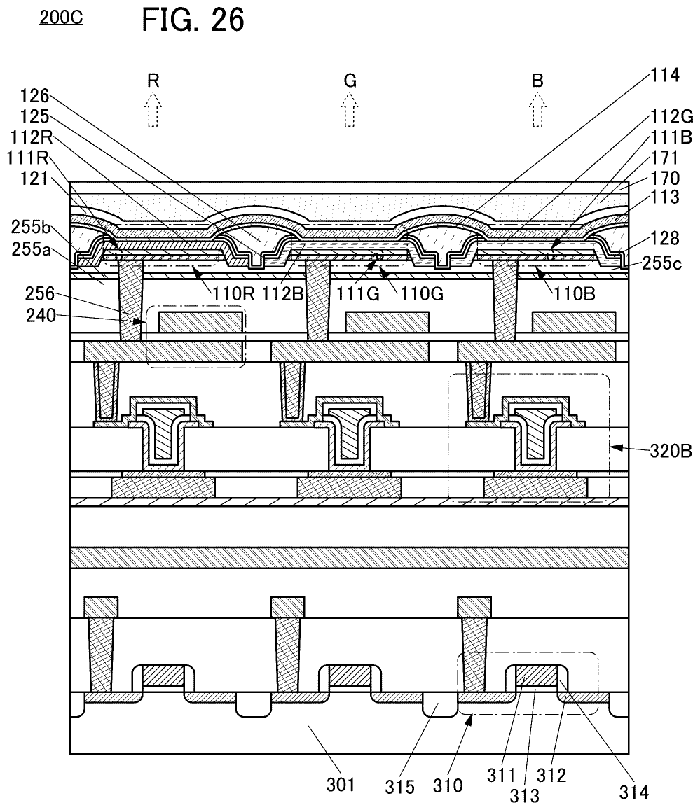

The display device 200C illustrated in FIG. 26 has a structure in which a transistor 310 whose channel is formed in a semiconductor substrate and the transistor 320 that is a vertical-channel transistor are stacked.

The transistor 310 is a transistor that includes a channel formation region in a substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and insulating layers 314. The conductive layer 311 serves as a gate electrode. The insulating layer 313 is positioned between the substrate 301 and the conductive layer 311 and serves as a gate insulating layer. The low-resistance region 312 is a region where the substrate 301 is doped with an impurity, and serves as one of a source and a drain. The insulating layers 314 are provided to cover side surfaces of the conductive layer 311.

An element isolation layer 315 is provided between two adjacent transistors 310 to be embedded in the substrate 301.

At least part of this embodiment can be implemented in combination with the other embodiments described in this specification as appropriate.

### Embodiment 4

In this embodiment, structure examples of a display device that can be employed for a display device manufactured using the transistor of one embodiment of the present invention will be described. The display device described below as an example can be employed for the pixel portion 284 and the like in Embodiment 3.

One embodiment of the present invention is a display device including light-emitting elements (also referred to as light-emitting devices). The display device includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers including different light-emitting materials. For example, when three kinds of light-emitting elements that emit red (R), green (G), and blue (B) light are included, a full-color display device can be achieved.

In the case of manufacturing a display device including a plurality of light-emitting elements of different emission colors, layers (light-emitting layers) including at least light-emitting materials each need to be formed in an island shape. In the case of separately forming some or all of EL layers, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve the high resolution and high aperture ratio of the display device. In addition, the outline of the layer might blur during evaporation, so that the thickness of an end portion might be reduced. That is, the thickness of an island-shaped light-emitting layer might vary from place to place. In the case of manufacturing a display device with a large size, high definition, or high resolution, a manufacturing yield might be reduced because of low dimensional accuracy of the metal mask and deformation due to heat or the like. Thus, a measure has been taken for a pseudo increase in resolution (also referred to as pixel density) by employing a unique pixel arrangement such as a PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to achieve a display device with high resolution and a high aperture ratio, which has been difficult to achieve. Moreover, since the EL layers can be formed separately, it is possible to achieve a display device that performs extremely clear display with high contrast and high display quality. Note that, fine patterning of the EL layers may be performed using both a metal mask and photolithography, for example.

Some or all of the EL layers can be physically divided from each other. This can inhibit leakage current flowing between adjacent light-emitting elements through a layer (also referred to as a common layer) shared by the light-emitting elements. Thus, it is possible to prevent unintended light emission due to crosstalk, so that a display device with extremely high contrast can be achieved. In particular, a display device having high current efficiency at low luminance can be achieved.

In one embodiment of the present invention, the display device can also be obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, some or all of the EL layers may be divided from each other by photolithography. Thus, leakage current through the common layer is inhibited; accordingly, a high-contrast display device can be achieved. In particular, when an element has a tandem structure where a plurality of light-emitting layers are stacked with a highly conductive intermediate layer therebetween, leakage current through the intermediate layer can be effectively prevented, so that a display device with high luminance, high resolution, and high contrast can be achieved.

In the case where the EL layer is processed by a photolithography method, part of the light-emitting layer is sometimes exposed to cause degradation. Thus, an insulating layer covering at least a side surface of the island-shaped light-emitting layer is preferably provided. The insulating layer may cover part of the top surface of an island-shaped EL layer. For the insulating layer, a material having a barrier property against water and oxygen is preferably used. For example, an inorganic insulating film in which water or oxygen is less likely to diffuse can be used. This can inhibit degradation of the EL layer and can achieve a highly reliable display device.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer (also referred to as LFP: Local Filling Planarization) serving as a planarization film. The resin layer has a function of a planarization film. This structure can inhibit disconnection of the common layer or the common electrode and can achieve a highly reliable display device.

More specific structure examples of the display device of one embodiment of the present invention are described below with reference to drawings.

### Structure Example 1

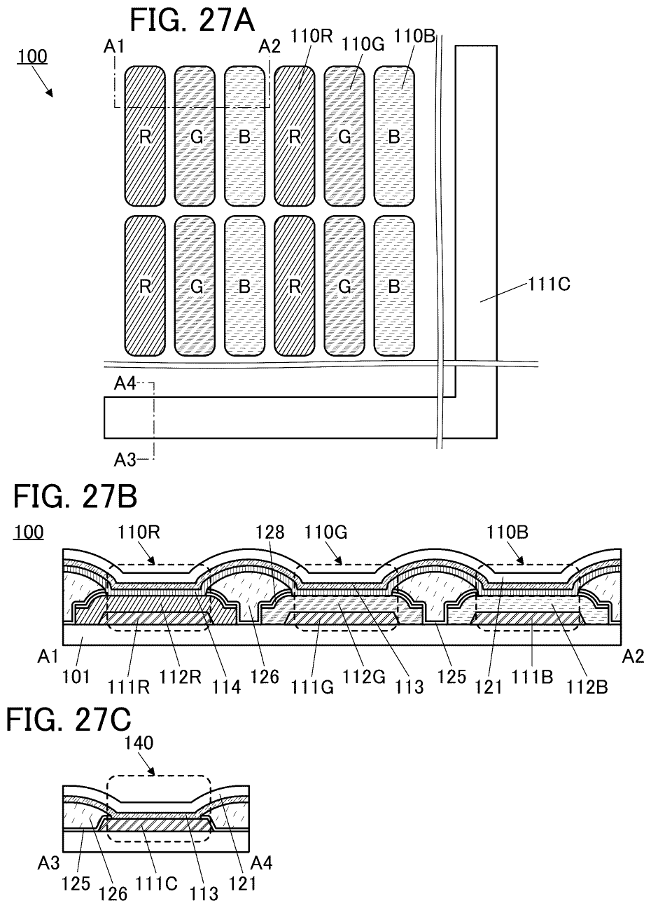

FIG. 27A illustrates a schematic top view of a display device 100 of one embodiment of the present invention. The display device 100 includes, over a substrate 101, a plurality of light-emitting elements 110R exhibiting red, a plurality of light-emitting elements 110G exhibiting green, and a plurality of light-emitting elements 110B exhibiting blue. In FIG. 27A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 27A illustrates what is called a stripe arrangement, in which the light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As a light-emitting substance included in the EL element, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given, for example. As the light-emitting substance included in the EL element, not only an organic compound but also an inorganic compound (a quantum dot material or the like) can be used.

FIG. 27A also illustrates a connection electrode 111C that is electrically connected to the common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided across two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like.

FIG. 27B and FIG. 27C are schematic cross-sectional views corresponding to the dashed-dotted line A1-A2 and the dashed-dotted line A3-A4 in FIG. 27A. FIG. 27B illustrates a schematic cross-sectional view of the light-emitting element 110R, the light-emitting element 110G, and the light-emitting element 110B, and FIG. 27C illustrates a schematic cross-sectional view of a connection portion 140 where the connection electrode 111C and the common electrode 113 are connected to each other.

The light-emitting element 110R includes the pixel electrode 111R, the organic layer 112R, the common layer 114, and the common electrode 113. The light-emitting element 110G includes the pixel electrode 111G, the organic layer 112G, the common layer 114, and the common electrode 113. The light-emitting element 110B includes the pixel electrode 111i, the organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R includes at least a light-emitting organic compound that emits red light. The organic layer 112G included in the light-emitting element 110G includes at least a light-emitting organic compound that emits green light. The organic layer 112B included in the light-emitting element 110B includes at least a light-emitting organic compound that emits blue light. Each of the organic layer 112R, the organic layer 112G, and the organic layer 112B can also be referred to as an EL layer and includes at least a layer including a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have light-transmitting properties and the common electrode 113 has a reflective property, a bottom-emission display device can be obtained. In contrast, when the pixel electrodes have reflective properties and the common electrode 113 has a light-transmitting property, a top-emission display device can be obtained. Note that when both the pixel electrodes and the common electrode 113 have light-transmitting properties, a dual-emission display device can also be obtained.

The protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a material (for example, also referred to as dust or particles) in a manufacturing step is easily removed by processing such as cleaning, which is preferable.

Note that in this specification and the like, a tapered shape indicates a shape in which at least part of a side surface of a structure is inclined to a substrate surface. For example, a tapered shape preferably includes a region where the angle formed between the inclined side surface and the substrate surface (such an angle is also referred to as a taper angle) is less than 90°.

The organic layer 112 is processed into an island shape by a photolithography method. Thus, the angle formed between the top surface and the side surface of an end portion of the organic layer 112 is approximately 90°. In contrast, an organic film formed using an FMM (Fine Metal Mask) or the like has a thickness that tends to gradually decrease with decreasing distance to an end portion, and has a top surface forming a slope in an area extending in the range of 1 μm to 10 μm to the end portion, for example. Thus, such an organic film has a shape whose top surface and side surface are difficult to distinguish from each other.

The insulating layer 125, the resin layer 126, and the layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to fill end portions of the organic layers 112 and a region between the two organic layers 112. The resin layer 126 has a top surface with a smooth protruding shape. The common layer 114 and the common electrode 113 are provided to cover the top surface of the resin layer 126.

The resin layer 126 serves as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated. The resin layer 126 can also be referred to as an LFP (Local Filling Planarization) layer.

An insulating layer including an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may include a material absorbing visible light. For example, the resin layer 126 itself may be made of a material absorbing visible light, or the resin layer 126 may include a pigment absorbing visible light. For example, for the resin layer 126, it is possible to use a resin that can be used as a color filter transmitting red, blue, or green light and absorbing other light, a resin that includes carbon black as a pigment and functions as a black matrix, or the like.

The insulating layer 125 is provided in contact with the side surfaces of the organic layers 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and serves as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126 to protect the side surfaces of the organic layer 112.

An insulating layer including an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that includes more oxygen than nitrogen in its composition, and nitride oxide refers to a material that includes more nitrogen than oxygen in its composition. For example, in the case where silicon oxynitride is described, it refers to a material that includes more oxygen than nitrogen in its composition. In the case where silicon nitride oxide is described, it refers to a material that includes more nitrogen than oxygen in its composition.

For the formation of the insulating layer 125, a sputtering method, a CVD method, a PLD method, an ALD method, or the like can be used. The insulating layer 125 is preferably formed by an ALD method that enables favorable coverage.

A structure may be employed in which a reflective film (e.g., a metal film including one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably serves as a planarization film. In that case, the top surface of the organic insulating film can be made flat, whereby the coverage with the inorganic insulating film thereover can be improved to achieve higher barrier property. This is preferable because the top surface of the protective layer 121 is made flat and a component (e.g., a color filter, an electrode of a touch sensor, a lens array, or the like) can be provided above the protective layer 121 while being less affected by an uneven shape caused by a lower structure.

FIG. 27C illustrates the connection portion 140 in which the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 27C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

### Structure Example 2

A display device whose structure is partly different from that of the above structure example 1 is described below. Note that the above description can be referred to for portions common to those in the above structure example 1, and the description is omitted in some cases.

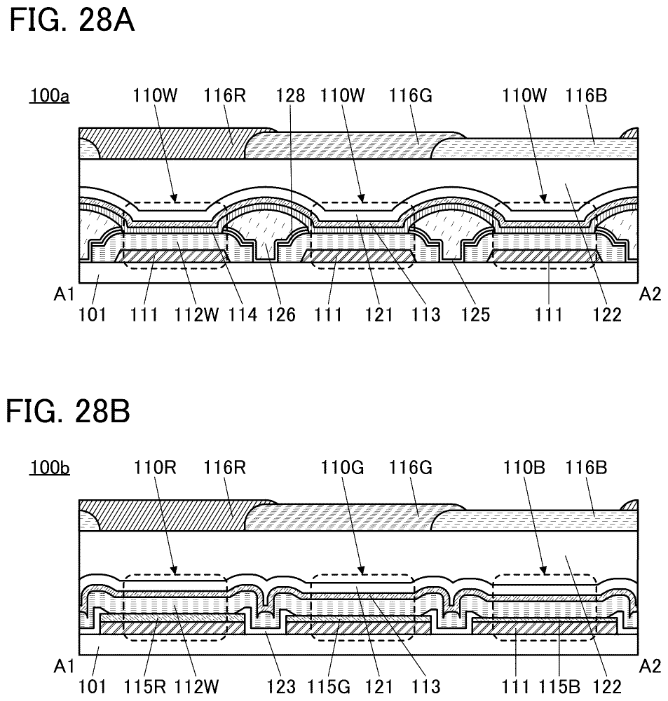

FIG. 28A illustrates a schematic cross-sectional view of a display device 100a. The display device 100a is different from the display device 100 mainly in the structure of the light-emitting element and including a coloring layer.

The display device 100a includes light-emitting elements 110W that emit white light. The light-emitting elements 110W each include the pixel electrode 111, an organic layer 112W, the common layer 114, and the common electrode 113. The organic layer 112W emits white light. For example, the organic layer 112W can be configured to include two or more kinds of light-emitting materials whose emission colors are complementary colors. For example, the organic layer 112W can be configured to include a light-emitting organic compound that emits red light, a light-emitting organic compound that emits green light, and a light-emitting organic compound that emits blue light. Alternatively, the organic layer 112W may include a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display device can achieve high contrast and high color reproducibility.

An insulating layer 122 that serves as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 is a formation surface on which the coloring layer 116R, the coloring layer 116G, and the coloring layer 116B are formed. Thus, with a flat top surface of the insulating layer 122, the thickness of the coloring layer 116R or the like can be uniform and color purity can be increased. Note that when the thickness of the coloring layer 116R or the like is non-uniform, the amount of light absorption varies depending on a place in the coloring layer 116R, which might decrease the color purity.

### Structure Example 3

FIG. 28B illustrates a schematic cross-sectional view of a display device 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and serve as an optical adjustment layer.

A film that reflects visible light is used for the pixel electrode 111 and a film having a property of reflecting and transmitting visible light is used for the common electrode 113, so that a micro resonator (microcavity) structure can be achieved. In that case, by adjusting the thicknesses of the conductive layer 115R, the conductive layer 115G, and the conductive layer 115B to obtain optimal optical path length, light with different wavelengths and increased intensities can be obtained from the light-emitting element 110R, the light-emitting element 110G, and the light-emitting element 110B even when the organic layer 112 that emits white light is used.

Furthermore, the coloring layer 116R, the coloring layer 116G, and the coloring layer 116B are provided on the optical paths of the light-emitting element 110R, the light-emitting element 110G, and the light-emitting element 110B, respectively, so that light with high color purity can be obtained.

An insulating layer 123 that covers an end portion of the pixel electrode 111 and an end portion of a conductive layer 115 is provided. An end portion of the insulating layer 123 preferably has a tapered shape. When the insulating layer 123 is provided, coverage with the organic layer 112W, the common electrode 113, the protective layer 121, and the like provided over the insulating layer 123 can be increased.

The organic layer 112W and the common electrode 113 are each provided as one continuous film shared by the light-emitting elements. Such a structure is preferable because the manufacturing process of the display device can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Accordingly, leakage current generated between adjacent light-emitting elements through the organic layer 112W can be inhibited without processing the organic layer 112W by a photolithography method or the like.

The above is the description of the structure examples of the display device.

At least part of this embodiment can be implemented in combination with the other embodiments described in this specification as appropriate.

### Embodiment 5

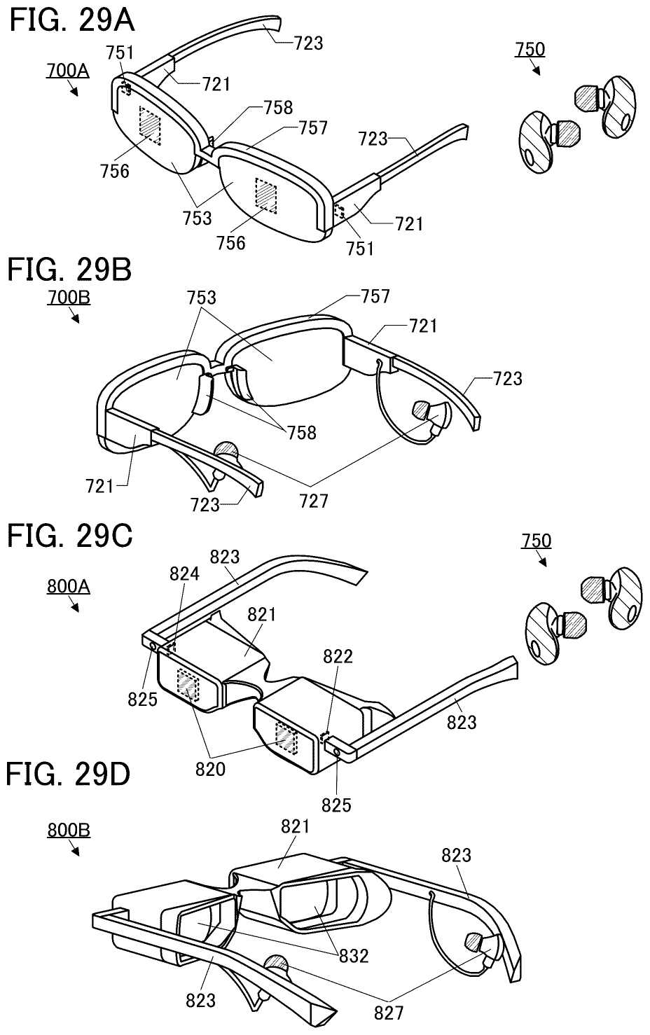

In this embodiment, electronic appliances of one embodiment of the present invention will be described with reference to FIG. 29 to FIG. 31.

Electronic appliances in this embodiment each include the display panel (display device) employing the transistor of one embodiment of the present invention in a display portion. The display device of one embodiment of the present invention can easily achieve higher resolution and higher definition and can achieve high display quality. Thus, the display device of one embodiment of the present invention can be used for display portions of a variety of electronic appliances.

Examples of the electronic appliances include a digital camera, a digital video camera, a digital photo frame, a cellular phone, a portable game machine, a portable information terminal, and an audio reproducing device, in addition to electronic appliances with comparatively large screens, such as a television device, a desktop or laptop personal computer, a monitor for a computer or the like, digital signage, and a large game machine such as a pachinko machine.

In particular, the display panel of one embodiment of the present invention can have higher resolution, and thus can be suitably used for an electronic appliance having a comparatively small display portion. Examples of such an electronic appliance include wristwatch-type and bracelet-type information terminal devices (wearable devices) and a wearable device that can be worn on a head, such as a device for VR such as a head-mounted display, a glasses-type device for AR, or a device for MR.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, the definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display panel with one or both of high definition and high resolution, realistic sensation, sense of depth, and the like can be further increased. Furthermore, there is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic appliance in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic appliance in this embodiment can have a variety of functions. For example, the electronic appliance can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head are described with reference to FIG. 29A to FIG. 29D. These wearable devices have one or both of a function of displaying AR contents and a function of displaying VR contents. Note that the wearable devices may have a function of displaying SR or MR contents, in addition to AR and VR contents. The electronic appliance having a function of displaying contents of at least one of AR, VR, SR, MR, and the like enables the user to reach a higher level of immersion.

An electronic appliance 700A illustrated in FIG. 29A and an electronic appliance 700B illustrated in FIG. 29B each include a pair of display panels 751, a pair of housings 721, a communication portion (not illustrated), a pair of wearing portions 723, a control portion (not illustrated), an imaging portion (not illustrated), a pair of optical members 753, a frame 757, and a pair of nose pads 758.

The display panel of one embodiment of the present invention can be employed for the display panel 751. Thus, the electronic appliance can perform display with extremely high resolution.

The electronic appliance 700A and the electronic appliance 700B can each project images displayed on the display panels 751 onto display regions 756 of the optical members 753. Since the optical members 753 have a light-transmitting property, the user can see images displayed on the display regions that are superimposed on transmission images seen through the optical members 753. Thus, the electronic appliance 700A and the electronic appliance 700B are electronic appliances capable of AR display.

In each of the electronic appliance 700A and the electronic appliance 700B, a camera capable of capturing images of the front side may be provided as the imaging portion. Furthermore, when each of the electronic appliance 700A and the electronic appliance 700B is provided with an acceleration sensor such as a gyroscope sensor, the orientation of a user's head can be sensed and an image corresponding to the orientation can be displayed on the display region 756.

The communication portion includes a wireless communication device, and a video signal and the like can be supplied by the wireless communication device. Note that instead of the wireless communication device or in addition to the wireless communication device, a connector to which a cable supplied with a video signal and a power potential can be connected may be provided.

Each of the electronic appliance 700A and the electronic appliance 700B is provided with a battery so that charging can be performed wirelessly and/or by wire.

A touch sensor module may be provided in the housing 721. The touch sensor module has a function of detecting a touch on an outer surface of the housing 721. A tap operation, a slide operation, or the like by the user can be detected with the touch sensor module, so that a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

A variety of touch sensors can be employed for the touch sensor module. For example, touch sensors of a variety of types such as a capacitive type, a resistive film type, an infrared type, an electromagnetic induction type, a surface acoustic wave type, and an optical type can be employed. In particular, a capacitive sensor or an optical sensor is preferably employed for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic appliance 800A illustrated in FIG. 29C and an electronic appliance 800B illustrated in FIG. 29D each include a pair of display portions 820, a housing 821, a communication portion 822, a pair of wearing portions 823, a control portion 824, a pair of imaging portions 825, and a pair of lenses 832.

The display panel of one embodiment of the present invention can be employed in the display portion 820. Thus, the electronic appliance can perform display with extremely high resolution. This enables the user to feel a high sense of immersion.

The display portions 820 are positioned inside the housing 821 to be seen through the lenses 832. Furthermore, when the pair of display portions 820 display different images, 3D display using parallax can be also performed.

Each of the electronic appliance 800A and the electronic appliance 800B can be regarded as an electronic appliance for VR. The user who wears the electronic appliance 800A or the electronic appliance 800B can see images displayed on the display portions 820 through the lenses 832.

The electronic appliance 800A and the electronic appliance 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lens 832 and the display portion 820 is preferably included.

The electronic appliance 800A or the electronic appliance 800B can be worn on the user's head with the wearing portions 823. Note that FIG. 29C and the like illustrate examples where the wearing portion 823 has a shape like a temple of glasses; however, one embodiment of the present invention is not limited thereto. The wearing portion 823 can have any shape with which the user can wear and can have a shape of a helmet or a band, for example.

The imaging portion 825 has a function of obtaining external information. Data obtained by the imaging portion 825 can be output to the display portion 820. An image sensor can be used for the imaging portion 825. Moreover, a plurality of cameras may be provided to support a plurality of fields of view, such as a telescope field of view and a wide field of view.

Note that although an example where the imaging portion 825 is included is shown here, a range sensor that is capable of measuring the distance between the user and an object (hereinafter such a sensor is also referred to as a sensing portion) is provided. In other words, the imaging portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more information can be obtained and a gesture operation with higher accuracy is possible.

The electronic appliance 800A may include a vibration mechanism that functions as bone-conduction earphones. For example, any one or more of the display portion 820, the housing 821, and the wearing portion 823 can include the vibration mechanism. Thus, without additionally requiring an audio device such as headphones, earphones, or a speaker, the user can enjoy a video and sound only by wearing the electronic appliance 800A.

The electronic appliance 800A and the electronic appliance 800B may each include an input terminal. To the input terminal, a cable for supplying a video signal from a video output device or the like, power for charging a battery provided in the electronic appliance, and the like can be connected.

An electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A illustrated in FIG. 29A has a function of transmitting information to the earphones 750 with the wireless communication function. As another example, the electronic appliance 800A illustrated in FIG. 29C has a function of transmitting information to the earphones 750 with the wireless communication function.

Alternatively, the electronic appliance may include an earphone portion. The electronic appliance 700B illustrated in FIG. 29B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic appliance 800B illustrated in FIG. 29D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of what is called a headset by including the audio input mechanism.

As described above, both the glasses-type device (the electronic appliance 700A, the electronic appliance 700B, or the like) and the goggles-type device (the electronic appliance 800A, the electronic appliance 800B, or the like) are suitable for the electronic appliance of one embodiment of the present invention.

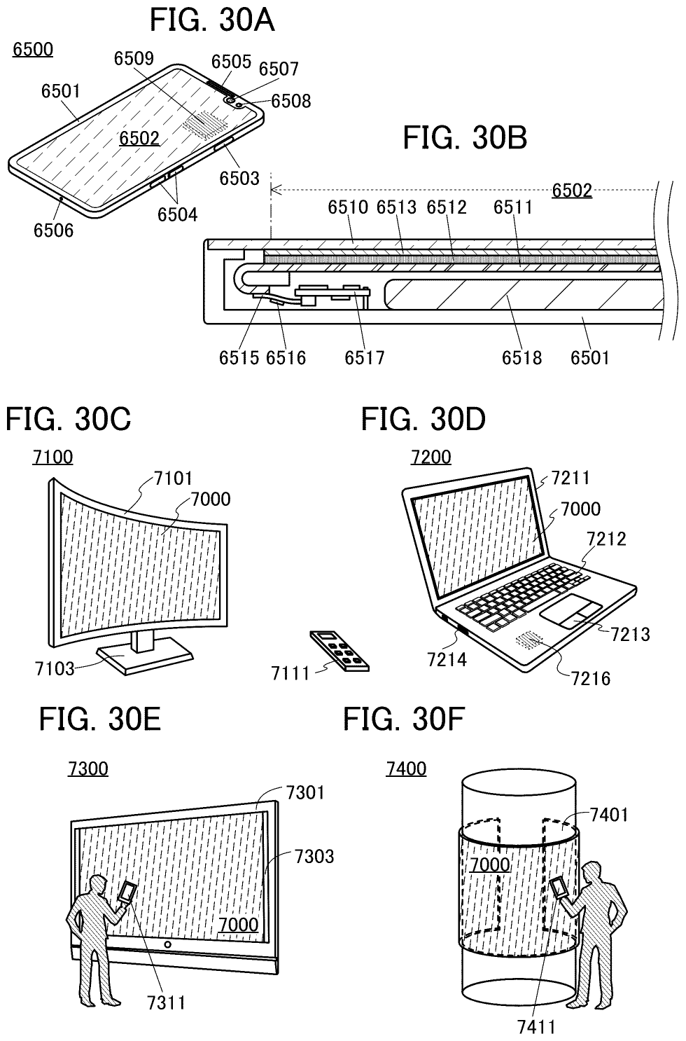

An electronic appliance 6500 illustrated in FIG. 30A is a portable information terminal device that can be used as a smartphone.

The electronic appliance 6500 includes a housing 6501, a display portion 6502, a power button 6503, buttons 6504, a speaker 6505, a microphone 6506, a camera 6507, a light source 6508, a control device 6509, and the like. The display portion 6502 has a touch panel function. Note that one or more selected from a CPU, a GPU, and a memory device are included as the control device 6509, for example. The semiconductor device of one embodiment of the present invention can be employed for the display portion 6502, the control device 6509, and the like. The semiconductor device of one embodiment of the present invention is suitably used for the control device 6509 because power consumption can be reduced.

The display panel of one embodiment of the present invention can be employed for the display portion 6502.

FIG. 30B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be employed for the display panel 6511. Thus, an extremely lightweight electronic appliance can be achieved. In addition, since the display panel 6511 is extremely thin, the battery 6518 with high capacity can be mounted while the thickness of the electronic appliance is reduced. Moreover, part of the display panel 6511 is folded back so that a connection portion with the FPC 6515 is provided on the back side of a pixel portion, so that an electronic appliance with a narrow bezel can be achieved.

FIG. 30C illustrates an example of a television device. In a television device 7100, a display portion 7000 is incorporated in a housing 7101. Here, a structure in which the housing 7101 is supported by a stand 7103 is illustrated.

Operation of the television device 7100 illustrated in FIG. 30C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and a video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 30D illustrates an example of a laptop personal computer. A laptop personal computer 7200 includes a housing 7211, a keyboard 7212, a pointing device 7213, an external connection port 7214, a control device 7216, and the like. The display portion 7000 is incorporated in the housing 7211. One or more selected from a CPU, a GPU, and a memory device are included as the control device 7216, for example. The semiconductor device of one embodiment of the present invention can be employed for the display portion 7000, the control device 7216, and the like. The semiconductor device of one embodiment of the present invention is suitably used for the control device 7216 because power consumption can be reduced.

FIG. 30E and FIG. 30F illustrate examples of digital signage.

Digital signage 7300 illustrated in FIG. 30E includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 30F is digital signage 7400 attached to a cylindrical pillar 7401. The digital signage 7400 includes the display portion 7000 provided along a curved surface of the pillar 7401.

The larger display portion 7000 can increase the amount of information that can be provided at a time. The larger display portion 7000 attracts more attention, so that advertising effects can be increased, for example.

The use of a touch panel in the display portion 7000 is preferable because in addition to display of an image or a moving image on the display portion 7000, an intuitive operation by the user is possible. Moreover, in the case where the display panel of one embodiment of the present invention is used for providing information such as route information or traffic information, usability can be increased by an intuitive operation.

As illustrated in FIG. 30E and FIG. 30F, it is preferable that the digital signage 7300 or the digital signage 7400 can work with an information terminal device 7311 or an information terminal device 7411 such as a user's smartphone through wireless communication. For example, information of an advertisement displayed on the display portion 7000 can be displayed on a screen of the information terminal device 7311 or the information terminal device 7411. Furthermore, by the operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

The display panel of one embodiment of the present invention can be employed for the display portion 7000 illustrated in each of FIG. 30C to FIG. 30F.

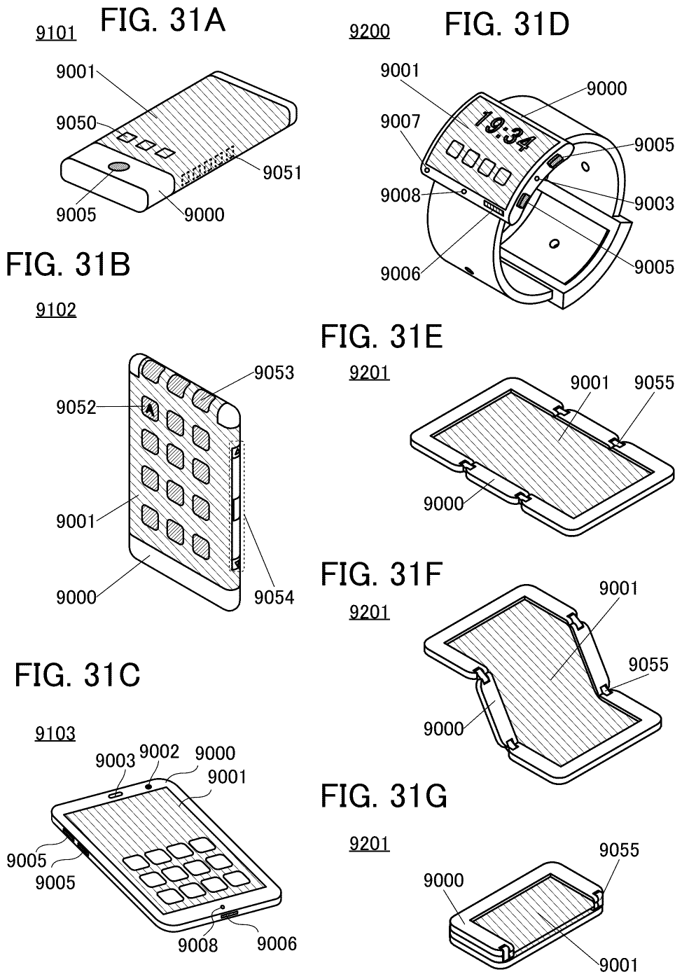

Electronic appliances illustrated in FIG. 31A to FIG. 31G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, a distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic appliances illustrated in FIG. 31A to FIG. 31G have a variety of functions. For example, the electronic appliances can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data recorded in a recording medium. Note that the functions of the electronic appliances are not limited thereto, and the electronic appliances can have a variety of functions. The electronic appliances may include a plurality of display portions. In addition, the electronic appliance may each be provided with a camera or the like and have a function of taking a still image or a moving image and storing the taken image in a recording medium (an external recording medium or a recording medium incorporated in the camera), a function of displaying the taken image on the display portion, or the like.

The electronic appliance illustrated in FIG. 31A to FIG. 31G are described in detail below.

FIG. 31A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. In addition, the portable information terminal 9101 can display characters and image information on its plurality of surfaces. FIG. 31A illustrates an example in which three icons 9050 are displayed. Furthermore, information 9051 indicated by dashed rectangles can be displayed on another surface of the display portion 9001. Examples of the information 9051 include notification of incoming e-mails, SNS, calls, and the like; the titles and senders of e-mails, SNS, and the like; dates; time; remaining battery; and radio field intensity. Alternatively, the icon 9050 or the like may be displayed at the position where the information 9051 is displayed.

FIG. 31B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 in a position that can be observed from above the portable information terminal 9102, with the portable information terminal 9102 put in a breast pocket of his/her clothes. The user can see display without taking out the portable information terminal 9102 from the pocket and determine whether to answer a call, for example.

FIG. 31C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on a front surface of the housing 9000; the operation keys 9005 as buttons for operations on a left side surface of the housing 9000; and the connection terminal 9006 on a bottom surface.

FIG. 31D is a perspective view illustrating a wristwatch-type portable information terminal 9200. For example, the portable information terminal 9200 can be used as a Smartwatch (registered trademark). A display surface of the display portion 9001 is provided to be curved, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 31E to FIG. 31G are perspective views illustrating a foldable portable information terminal 9201. FIG. 31E is a perspective view of an opened state of the portable information terminal 9201, FIG. 31G is a perspective view of a folded state thereof, and FIG. 31F is a perspective view of a state in the middle of change from one of FIG. 31E and FIG. 31G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 0.1 mm and less than or equal to 150 mm.

At least part of this embodiment can be implemented in combination with the other embodiments described in this specification as appropriate.

### Embodiment 6

In this embodiment, application examples of a semiconductor device of one embodiment of the present invention will be described. The semiconductor device of one embodiment of the present invention can be used for an electronic component, an electronic appliance, a large computer, space equipment, and a data center (also referred to as DC), for example. An electronic component, an electronic appliance, a large computer, space equipment, and a data center each using the semiconductor device of one embodiment of the present invention are effective in achieving high performance, e.g., reducing power consumption.

An electronic component or the like employing the semiconductor device of one embodiment of the present invention can be applied to the electronic appliance illustrated as an example in Embodiment 5.

### [Electronic Component]

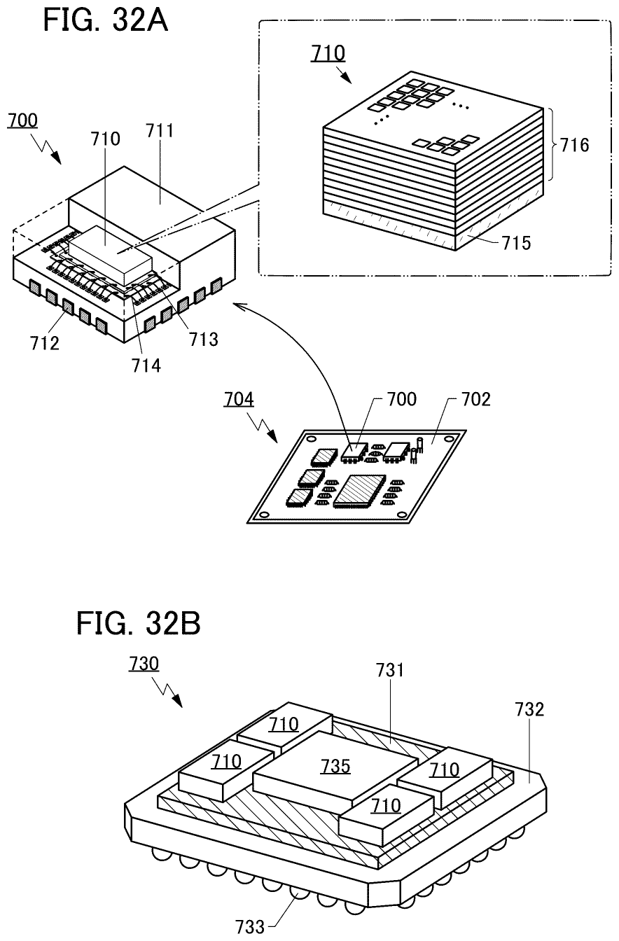

FIG. 32A illustrates a perspective view of a substrate (a mounting board 704) on which an electronic component 700 is mounted. The electronic component 700 illustrated in FIG. 32A includes a semiconductor device 710 in a mold 711. FIG. 32A omits illustrations of some parts to show the inside of the electronic component 700. The electronic component 700 includes lands 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected on the printed circuit board 702, so that the mounting board 704 is completed.

The semiconductor device 710 includes a driver circuit layer 715 and a memory layer 716. Note that the memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the memory layer 716, the monolithic stacked-layer structure is difficult to form as compared with the case where OS transistors are used for the memory layer 716. Therefore, the OS transistors are superior to the Si transistors in the monolithic stacked-layer structure.

The semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 32B illustrates a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate.” In some cases, a through electrode is provided in the interposer 731 to be used for electrically connecting an integrated circuit and the package substrate 732. In a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in the expansion coefficient between an integrated circuit and the interposer is less likely to occur. Furthermore, a surface of a silicon interposer has high planarity, and poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

A heat sink (a radiator plate) may be provided to overlap with the electronic component 730. In the case where a heat sink is provided, integrated circuits provided on the interposer 731 preferably have the same height. For example, in the electronic component 730 described in this embodiment, the semiconductor devices 710 and the semiconductor device 735 preferably have the same height.

Electrodes 733 may be provided on a bottom part of the package substrate 732 to mount the electronic component 730 on another substrate. FIG. 32B illustrates an example in which the electrodes 733 are formed of solder balls. When the solder balls are provided in a matrix on the bottom part of the package substrate 732, BGA (Ball Grid Array) mounting can be achieved. Alternatively, the electrodes 733 may be formed of conductive pins. When the conductive pins are provided in a matrix on the bottom part of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Large Computer]

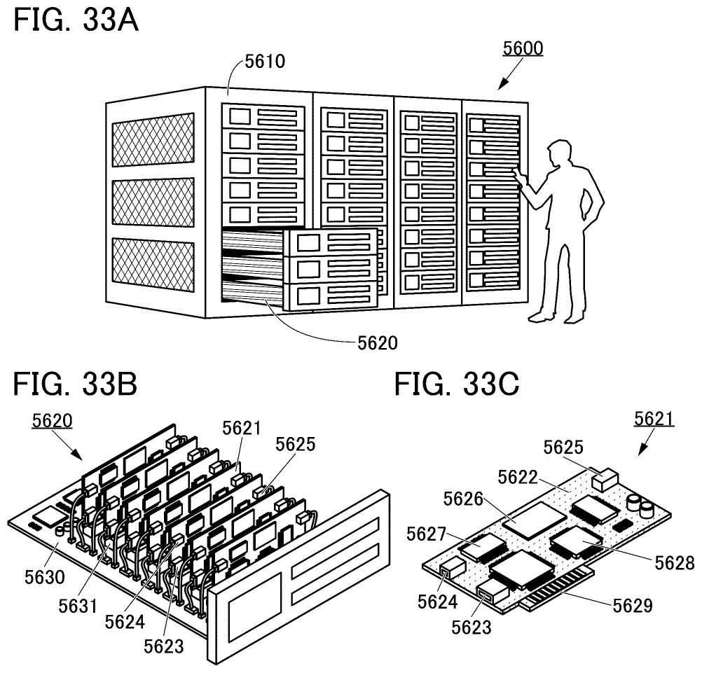

FIG. 33A illustrates a perspective view of a large computer 5600. In the large computer 5600, a plurality of rack mount computers 5620 are stored in a rack 5610. Note that the large computer 5600 may also be referred to as a supercomputer.

FIG. 33B illustrates a perspective view of an example of the computer 5620. The computer 5620 includes a motherboard 5630. The motherboard 5630 is provided with a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

FIG. 33C illustrates an example of the PC card 5621. The PC card 5621 is a processing board provided with a CPU, a GPU, a memory device, and the like, for example. The PC card 5621 includes a board 5622, and the connection terminal 5623, the connection terminal 5624, the connection terminal 5625, an electronic component 5626, an electronic component 5627, an electronic component 5628, a connection terminal 5629, and the like that are mounted on the board 5622. Note that FIG. 33C illustrates components other than the electronic component 5626, the electronic component 5627, and the electronic component 5628.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The electronic component 5626 includes a terminal (not illustrated) for inputting and outputting signals, and when the terminal is inserted in a socket (not illustrated) of the board 5622, the electronic component 5626 and the board 5622 can be electrically connected to each other.

The electronic component 5627 and the electronic component 5628 each include a plurality of terminals, and when the terminals are reflow-soldered, for example, to wirings of the board 5622, the electronic component 5627 and the electronic component 5628 can be mounted. Examples of the electronic component 5627 include an FPGA, a GPU, and a CPU. The electronic component 730 can be used as the electronic component 5627, for example. An example of the electronic component 5628 is a memory device. The electronic component 700 can be used as the electronic component 5628, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment.

The semiconductor device of one embodiment of the present invention includes an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification may include one or more of the thermosphere, the mesosphere, and the stratosphere.

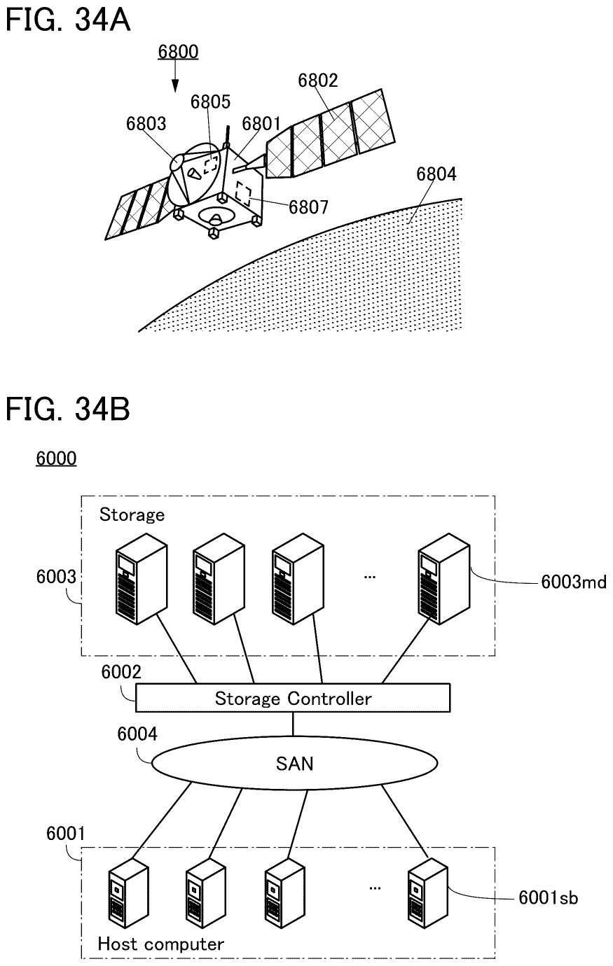

FIG. 34A illustrates an artificial satellite 6800 as an example of space equipment. The artificial satellite 6800 includes a body 6801, solar panels 6802, an antenna 6803, a secondary battery 6805, and a control device 6807. Note that FIG. 34A illustrates a planet 6804 in outer space, for example.

Although not illustrated in FIG. 34A, a battery management system (also referred to as a BMS) or a battery control circuit may be provided in the secondary battery 6805. An OS transistor is suitably used in the battery management system or the battery control circuit because low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 may be provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed using one or more selected from a CPU, a GPU, and a memory device, for example. Note that the semiconductor device that is one embodiment of the present invention and includes an OS transistor is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Although the artificial satellite is illustrated as an example of space equipment in this embodiment, the present invention is not limited thereto. The semiconductor device of one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device of one embodiment of the present invention can be suitably used for, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device of one embodiment of the present invention for a storage system employed in a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve a data center that stably operates even in a high-temperature environment. Thus, the reliability of the data center can be increased.

FIG. 34B illustrates a storage system applicable to a data center. A storage system 6000 illustrated in FIG. 34B includes a plurality of servers 6001sb as a host 6001 (indicated as “Host Computer” in the diagram). In addition, the storage system 6000 includes a plurality of memory devices 6003md as a storage 6003 (indicated as “Storage” in the diagram). In the illustrated example, the host 6001 and the storage 6003 are connected through a storage area network 6004 (indicated as “SAN” in the diagram) and a storage control circuit 6002 (indicated as “Storage Controller” in the diagram).

The host 6001 corresponds to a computer that accesses data stored in the storage 6003. The hosts 6001 may be connected to each other through a network.

The data access speed, i.e., the time taken for storing and outputting data, of the storage 6003 is shortened by using a flash memory, but is considerably longer than the data access speed of a DRAM that can be used as a cache memory in a storage. In the storage system, in order to solve the problem of low access speed of the storage 6003, a cache memory is usually provided in the storage to shorten the time for storing and outputting data.

The cache memories are used in the storage control circuit 6002 and the storage 6003. Data transmitted between the host 6001 and the storage 6003 are stored in the cache memories in the storage control circuit 6002 and the storage 6003 and then output to the host 6001 or the storage 6003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device of one embodiment of the present invention for one or more selected from an electronic component, an electronic appliance, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

At least part of this embodiment can be implemented in combination with the other embodiments described in this specification as appropriate.

### REFERENCE NUMERALS

10a: transistor, 10b: transistor, 10c: transistor, 10d: transistor, 10e: transistor, 10f: transistor, 10g: transistor, 10h: transistor, 10i: transistor, 10j: transistor, 10: transistor, 11: insulating layer, 15f: insulating film, 15: insulating layer, 16f: insulating film, 16: insulating layer, 17f: insulating film, 17: insulating layer, 20a: opening, 20b: opening, 20c: opening, 21f: semiconductor film, 21i: channel formation region, 21n: low-resistance region, 21: semiconductor layer, 22: insulating layer, 23: conductive layer, 26: conductive layer, 30a: memory cell, 30: memory cell, 31: conductive layer, 32: conductive layer, 34: conductive layer, 41a: insulating layer, 41b: insulating layer, 41c: insulating layer, 41: insulating layer, 42: insulating layer, 44: insulating layer, 47a: insulating layer, 47b: insulating layer, 47c: insulating layer, 47: insulating layer, 48: insulating layer, 50: capacitor, 51: conductive layer, 52: conductive layer, 53: insulating layer, 60: memory unit, 60[a,b]: memory unit, 80[m]: layer, 61: conductive layer, 62: conductive layer, 63: conductive layer, 65: insulating layer, 70: transistor, 71: semiconductor layer, 72: insulating layer, 73: conductive layer, 74: conductive layer, 75: conductive layer, 80: layer, 90: transistor, 91: substrate, 92: semiconductor region, 93: insulating layer, 94: conductive layer, 95a: low-resistance region, 95b: low-resistance region

1. A semiconductor device comprising:
a first insulating layer;
a second insulating layer; and
a transistor, the transistor comprising:
a first conductive layer below the first insulating layer;
a second conductive layer;
a third conductive layer;
a semiconductor layer over the first insulating layer; and
a third insulating layer,
wherein an opening provided in the first insulating layer reaches the first conductive layer,
wherein the semiconductor layer comprises a first portion in contact with a top surface of the first conductive layer in the opening of the first insulating layer and a second portion provided along a side surface of the first insulating layer in the opening of the first insulating layer, and
wherein the third insulating layer covers the semiconductor layer in the opening of the first insulating layer,
wherein the third conductive layer covers the third insulating layer in the opening of the first insulating layer,
wherein the second insulating layer covers the third conductive layer, and
wherein the second conductive layer comprises a first portion positioned over the third conductive layer with the second insulating layer therebetween and a second portion in contact with a third portion of the semiconductor layer which is positioned over the first insulating layer.

2. The semiconductor device according to claim 1,
wherein the second conductive layer comprises a third portion extending in a first direction,
wherein the third conductive layer comprises a portion extending in a second direction intersecting with the first direction, and
wherein the second conductive layer and the third conductive layer intersect with each other in a region overlapping with the opening of the first insulating layer.

3. The semiconductor device according to claim 1, further comprising:
a fourth insulating layer and a fifth insulating layer each positioned inside the opening of the first insulating layer,
wherein the fourth insulating layer is provided between the semiconductor layer and the first insulating layer and comprises a material less likely to diffuse hydrogen than the first insulating layer, and
wherein the fifth insulating layer is provided between the semiconductor layer and the fourth insulating layer and is configured to capture or fix hydrogen.

4. The semiconductor device according to claim 3, further comprising:
a sixth insulating layer positioned inside the opening of the first insulating layer,
wherein the sixth insulating layer is provided between the semiconductor layer and the fifth insulating layer and comprises an oxide.

5. The semiconductor device according to claim 1,
wherein a diameter of the opening of the first insulating layer in a top view is larger than a height of the opening of the first insulating layer in a cross-sectional view.

6. The semiconductor device according to claim 1,
wherein a diameter of the opening of the first insulating layer in a top view is more than or equal to twice as large as a height of the opening of the first insulating layer in a cross-sectional view.

7. The semiconductor device according to claim 1,
wherein at least one of the first conductive layer and the second conductive layer comprises ruthenium.

8. A semiconductor device comprising:
a first conductive layer;
a first insulating layer over the first conductive layer, the first insulating layer comprising a first opening reaching the first conductive layer;
a semiconductor layer over the first insulating layer, the semiconductor layer comprising a first portion in contact with a top surface of the first conductive layer in the first opening of the first insulating layer;
a second conductive layer in contact with the semiconductor layer;
a third insulating layer covering the semiconductor layer in the first opening of the first insulating layer;
a third conductive layer covering the third insulating layer in the first opening of the first insulating layer; and
a second insulating layer covering the third conductive layer,
wherein the second conductive layer comprises a first portion positioned over the third conductive layer with the second insulating layer therebetween.

9. A semiconductor device comprising:
a first conductive layer;
a first insulating layer over the first conductive layer, the first insulating layer comprising a first opening reaching the first conductive layer;
a semiconductor layer over the first insulating layer, the semiconductor layer comprising a first portion in contact with a top surface of the first conductive layer in the first opening of the first insulating layer;
a second conductive layer in contact with the semiconductor layer;
a third insulating layer covering the semiconductor layer in the first opening of the first insulating layer;
a third conductive layer covering the third insulating layer in the first opening of the first insulating layer;
a second insulating layer covering the third conductive layer; and
a fourth insulating layer and a fifth insulating layer between the first insulating layer and the semiconductor layer in the first opening of the first insulating layer,
wherein the second conductive layer comprises a first portion positioned over the third conductive layer with the second insulating layer therebetween, and
wherein the semiconductor layer comprises a channel formation region of a transistor.
